(19) United States
(12) Patent Application Publication
(10) Pub. No.: US 2025/0132746 A1
(43) Pub. Date: Apr. 24, 2025

(54) FILTERING APPARATUS, FILTER DEVICE, AND TRANSMISSION APPARATUS

(71) Applicant: Weiming Yin, Beijing (CN)

(72) Inventor: Jiliang Chen, Beijing (CN)

(21) Appl. No.: 18/696,058

(22) PCT Filed: Aug. 10, 2022
(86) PCT No.: PCT/CN2022/111503

§ 371 Date: May 17, 2024

(30) Foreign Application Priority Data
Sep. 27, 2021 (CN) 202111137982.5

(51) Int. Cl. H03H 7/06

(52) U.S. Cl. CPC H03H 7/06

(57) ABSTRACT

A filtering apparatus comprising at least two common-mode inductors and at least one differential-mode inductor, where the common-mode inductors and the differential-mode inductor each is a choke having two coils, and where magnetic fluxes generated by the two coils of each of the common-mode inductors when the common-mode signals flow through enhance each other, and magnetic fluxes generated by the two coils of each of the differential-mode inductors when the common-mode signals flow through counteract each other. One coil of each of the common-mode inductors is connected in series to one branch of a differential line in a sequence and the other coil is connected in series to the other branch of the differential line in the sequence, and each coil of each of the differential-mode inductors is connected between one of two branches of the differential line between adjacent common-mode inductors and ground.

### CROSS REFERENCE TO RELATED APPLICATIONS

This application is a National Stage application of International Application No. PCT/CN2022/111503 filed on Aug. 10, 2022, which claims priority to Chinese Application No. 202111137982.5 filed Sep. 27, 2021.

### BACKGROUND

### Field

The present disclosure relates to electronic circuit systems, and in particular relates to a filtering apparatus, a filtering device and a transmission apparatus for a differential line.

### Discussion of the Related Art

Throughout the electronics field, in response to the requirements of multi-functionality and high performance, processing speed and transmission speed of data are rising, and the communication rate requirements between electronic devices are further enhanced. With the development of serial bus technology, it has slowly formed a current dominant position in the high-speed interface. The serial bus technology is applied in many standards such as Universal Serial Bus, High Speed Serial Computer Expansion Bus Standard, Ethernet, Car Ethernet, Low Voltage Differential Signaling, and High-Definition Multimedia Interface.

Especially with the large increase of electronic devices in the design of automobiles, application of various data communication and autonomous driving technologies in automobiles, continuous development of video devices, in-vehicle entertainment devices and assisted driving technologies, and communication between different systems makes extensive use of serial data buses.

In high-speed serial data transmission, a differential transmission technology is generally used. The differential transmission technology is a communication method that transmits data by means of differential signals (also called differential-mode signals) of opposite phases. A receiving apparatus reads the serial data based on a difference between the two differential signals. The differential signals facilitate further high-speed signal transmission.

The differential signals facilitate reduction of electromagnetic interference. Because paths for transmitting the differential signals are parallel, and alternating current portions of ideal differential signals are equal in size and opposite in direction, most of the electromagnetic fields they radiate outward counteract each other, thereby resulting in lower electromagnetic radiation energy. Moreover, when there is space electromagnetic energy transmitted to the differential transmission path, noises often enter the transmission path in the form of common-mode noises (also known as common-mode signals) due to the nature of parallel-arrangement of differential signal cables. Within the received level tolerance limit of the signals, the differential signal receiver may exclude interference of the common-mode noise. Therefore, the data transmitted with the differential signal has a certain suppression effect on external common-mode noise.

In actual usage of the differential signals, the signals sent by a differential signal transmission circuit always contain a common-mode noise component due to a variety of reasons. For a differential signal receiving circuit, when the common-mode noises exceed its common-mode noise tolerance limit, it will result in loss of the received data, and even cause damage to the receiving circuit.

In the apparatuses that transmit data using the differential signals, a filtering circuit for the common-mode noises are required to be included in the circuit in order to further suppress undesirable effects of the common-mode noise. The filtering circuit includes a common-mode inductor, also known as a common-mode choke. For the differential signal transmission circuit, the common-mode inductor can reduce a common-mode current in signal transmission. For the receiving circuit, the common-mode inductor suppresses the level of the externally input common-mode noises within a permissible range of the receiver.

The circuits in FIG. 1A, FIG. 1B, and FIG. 1C are applied in filters that have been disclosed.

FIG. 1A shows a disclosed first filtering circuit that is a common-mode inductor, the function of which is to increase impedance of common-mode current in the line (“impedance” herein represents the ability that the devices such as resistors, capacitors, inductors and the like or the signaling lines limit the passage of current. This ability to limit the passage of current is caused by the intrinsic resistance of the devices or the lines themselves, by factors such as inductance, capacitance and the like of the devices or the lines themselves, or by a combination of the factors), thereby reducing the common-mode current on the lines. The disadvantage of this circuit is that the control of the common-mode current is dependent on the common-mode impedance of the single common-mode inductor.

FIG. 1B shows a disclosed second filtering circuit, in which a common-mode inductor is coupled in parallel with a differential-mode inductor (also called a differential-mode choke or normal-mode choke). Wherein the common-mode inductor has the same function as that in FIG. 1A, and the differential-mode inductor serves to shunt the common-mode current and perform impedance matching on the common-mode signals. This circuit has the following disadvantages.
(1) When the common-mode impedance of the differential-mode inductor is greater than the common-mode impedance of the signal line, the effect of the differential-mode inductor on the common-mode signals on the line is not apparent.
(2) In some designs, the common-mode impedance of the differential mode inductor is designed to be equal or close to the common-mode impedance of the signal line, so as to absorb the common-mode signals reflected by the common-mode choke. This design causes the frequency range of the filtering to be too narrow, and although the common-mode signals reflected by the common-mode inductor is absorbed by the differential mode inductor, the common-mode signals introduced by the differential signal drive circuit or differential cable will still reach the common-mode inductor along the path of the signal line. The attenuation of this part of the common-mode signals is not apparent.
(3) When the common-mode impedance of the differential inductor is much smaller than the common-mode impedance in the signal line, it may result in excessive common-mode current flowing through the differential signal drive circuit or negative reflection of the common-mode signals, which may lead to abnormal operation of the signal drive circuit.

FIG. 1C shows a disclosed third filtering circuit, in which each of left and right sides of a common-mode inductor is coupled in parallel with a differential-mode inductor, wherein the differential-mode instructors shunt the common-mode signals on both sides of the common-mode choke. This circuit has the following disadvantages.
(1) It contains the disadvantages contained in the circuit of FIG. 1B.
(2) Due to the low impedance characteristics of the differential-mode inductor on the right side for the common-mode signals, the noises on the ground plane are easily coupled to the cables of the signal line as common-mode noises.

### SUMMARY

In view of this, embodiments of the present disclosure provide a filtering apparatus, a filtering device, and a transmission apparatus. The filtering apparatus achieves multi-stage cascaded attenuation of the common-mode signals in the direction of transmission of the differential signals (for ease of comparison, the differential signals are denoted as the differential-mode signals and the common-mode noises are called the common-mode signals) by a filtering circuit of the common-mode signals which comprises a combination of a common-mode inductor and a differential-mode inductor sequentially connected and, does not produce excessive attenuation of the differential-mode signals in a wide bandwidth range, and has good attenuation effect. At the same time, the multi-stage cascaded attenuation of the common-mode signals coupled in from the receiving end is also achieved to protect an apparatus at the sending end of the differential signals.

In a first aspect, embodiments of the present disclosure provide a filtering apparatus for filtering common-mode signals in a differential line, wherein the filtering apparatus comprises: at least two common-mode inductors and at least one differential-mode inductor; the common-mode inductors each are a choke having two coils, and magnetic fluxes generated by the two coils of each of the common-mode inductors when common-mode signals flow through enhance each other, and wherein one coil of each of the common-mode inductors is connected in series to one branch of the differential line in a sequence, and the other coil of each of the common-mode inductors is connected in series to the other branch of the differential line in the sequence; the at least one differential-mode inductor each is a choke having two coils, and magnetic fluxes generated by the two coils of each of the at least one differential-mode inductor when the common-mode signals flow through counteract each other, wherein each coil of each of the at least one differential-mode inductor is connected between one of two branches of the differential line between adjacent common-mode inductors and the ground.

Thus, by means of the multi-stage cascaded filtering apparatus consisting of at least two common-mode inductors connected in series and at least one differential-mode inductor one of which every two common-mode inductors are connected in parallel with, multi-stage attenuation on the common-mode signals sent from the differential signal transmission circuit is performed, which better improves the signal-to-noise ratio of the differential line signals in a wider bandwidth; meanwhile, the multi-stage attenuation on the common-mode signals introduced from the loads of the differential signals and the common-mode signals introduced during the transmission is also performed, which has better attenuation effect and protects the differential signal transmission circuit. In addition, multi-stage filtering on the plane noises and the common-mode signals coupled through the cable is also performed, which further improves the signal-to-noise ratio of the differential line signals, and further decreases outward radiation of the noises from the data cable by cascading to reduce the common-mode signals.

In a possible implementation of the first aspect, the filtering apparatus further comprises: a differential-mode inductor connected between input terminals of the filtering apparatus and the ground, two coils of which are connected between the two branches of the differential line at the input terminals of the filtering apparatus and the ground, respectively.

Thus, by means of a differential-mode inductor connected between input terminals of the filtering apparatus and the ground, the impedance between the filtering apparatus and the differential signal output circuit is matched.

In a possible implementation of the first aspect, the filtering apparatus further comprises: a differential-mode inductor connected between output terminals of the filtering apparatus and the ground, two coils of which are connected between the two branches of the differential line at the output terminals of the filtering apparatus and the ground, respectively.

Thus, by means of a differential-mode inductor connected between output terminals of the filtering apparatus and the ground, the impedance between the filtering apparatus and the load line of the differential signals is matched.

In a possible implementation of the first aspect, the filtering apparatus further comprises: diodes connected between the two branches of the differential line at the input terminals of the filtering apparatus and the ground, which diodes each may be a unidirectional or bidirectional diode.

Thus, by means of diodes connected between the two branches of the differential line at the input terminals of the filtering apparatus and the ground, input amplitude limiting and anti-static of the filtering apparatus are realized.

In a possible implementation of the first aspect, the filtering apparatus further comprises: diodes connected between the two branches of the differential line at the output terminals of the filtering apparatus and the ground, which diodes each may be a unidirectional or bidirectional diode.

Thus, by means of diodes connected between the two branches of the differential line at the output terminals of the filtering apparatus and the ground, output amplitude limiting and anti-static of the filtering apparatus are realized.

In a possible implementation of the first aspect, said filtering apparatus further comprises: third circuits connected in series to the two branches of the differential line at the input terminals of the filtering apparatus, respectively, wherein the third circuits each includes at least one of an inductor, a resistor, a capacitor and a diode. The third circuits each are preferably a capacitor.

Thus, by means of third circuits connected in series to the two branches of the differential line at the input terminals of the filtering apparatus, respectively, and consisting of at least one of an inductor, a resistor, a capacitor and a diode, the direct current signals in the input signals are matched or isolated.

In a possible implementation of the first aspect, the filtering apparatus further comprises: third circuits connected in series to the two branches of the differential line at the output terminals of the filtering apparatus.

Thus, by means of third circuits connected in series to the two branches of the differential line at the output terminals of the filtering apparatus, respectively, and consisting of at least one of an inductor, a resistor, a capacitor and a diode, the direct current signals in the output signals are matched or isolated.

In a possible implementation of the first aspect, the filtering apparatus further comprises: fourth circuits connected between ground ends of the two coils of each of the differential-mode inductors and the ground, wherein the fourth circuits each includes at least one of an inductor, a resistor, a capacitor, and a diode. The fourth circuits each are preferably a capacitor.

Thus, by means of fourth circuits connected between ground ends of the two coils of each of the differential-mode inductors and the ground and each consisting of at least one of an inductor, a resistor, a capacitor, and a diode, matching or isolation of the direction current signals between the filtering apparatus and the ground are realized, and matching or isolation between the ground of the upper stage differential signal output circuit and the ground of the lower stage differential signal load circuit are realized at the same time.

In a possible implementation of the first aspect, ground terminals of the two coils of each of a plurality of differential-mode inductors are merged.

Thus, by means of merging of the ground terminals of the two coils of each of a plurality of differential-mode inductors, the circuit of the filtering apparatus is simplified. If it is connected to the ground via the fourth circuit after the merging, the number of fourth circuits is reduced, which further simplifying the circuit of the filtering apparatus.

In a second aspect, embodiments of the present disclosure provide a filtering apparatus for filtering common-mode signals in a differential line, which comprises: at least two common-mode inductors and at least one first circuit, wherein the common-mode inductors each are a choke having two coils and magnetic fluxes generated by the two coils of each of the common-mode inductors when common-mode signals flow through enhance each other, and the at least one first circuit each includes two second circuits, which each is a capacitor or a series circuit of a capacitor and a resistor, wherein one coil of each of the common-mode inductors is connected in series to one branch of the differential line in a sequence, and the other coil of each of the common-mode inductors is connected in series to the other branch of the differential line in the sequence; and each of the second circuits is connected between one of two branches of the differential line between adjacent common-mode inductors and the ground.

Thus, by means of the multi-stage cascaded filtering apparatus consisting of at least two common-mode inductors connected in series and two capacitors or the series circuits of capacitors and resistors that are connected between the branches of the differential line between every two common-mode inductors and the ground, multi-stage and combined-effect attenuation on the common-mode signals sent from the differential signal transmission circuit is performed, which has small impact on the differential signals and better improves the signal-to-noise ratio of the differential line signals in a wider bandwidth; meanwhile, the multi-stage and combined-effect attenuation on the common-mode signals introduced from the loads of the differential signals and the common-mode signals introduced during the transmission is also performed, which has better attenuation effect and protects the differential signal transmission circuit. In addition, multi-stage filtering on the plane noises and the common-mode signals coupled through the cable is also performed, which further improves the signal-to-noise ratio of the differential line signals, and further decreases outward radiation of the noises from the data cable by cascading to reduce the common-mode signals.

In a possible implementation of the second aspect, the filtering apparatus further comprises: second circuits connected between the two branches of the differential line at input terminals of the filtering apparatus and the ground.

Thus, by means of the capacitors or the series circuits of capacitors and resistors that are connected between the two branches of the differential line at input terminals of the filtering apparatus and the ground, impedance matching of the filtering apparatus with the differential signal output circuit and the corresponding differential transmission line is realized.

In a possible implementation of the second aspect, the filtering apparatus further comprises: second circuits connected between the two branches of the differential line at output terminals of the filtering apparatus and the ground.

Thus, by means of the capacitors or the series circuits of capacitors and resistors that are connected between the two branches of the differential line at output terminals of the filtering apparatus and the ground, impedance matching between the filtering apparatus and a differential signal transmission cable or a board differential wiring or load circuit is realized.

In a possible implementation of the second aspect, said filtering apparatus further comprises: diodes connected between the two branches of the differential line at the input terminals of the filtering apparatus and the ground, which diodes each is a unidirectional or bidirectional diode.

Thus, by means of diodes connected between the two branches of the differential line at the input terminals of the filtering apparatus and the ground, the input amplitude limiting and anti-static of the filtering apparatus are realized.

In a possible implementation of the second aspect, said filtering apparatus further comprises: diodes connected between the two branches of the differential line at the output terminals of the filtering apparatus and the ground, which diodes each is a unidirectional or bidirectional diode.

Thus, by means of diodes connected between the two branches of the differential line at the output terminals of the filtering apparatus and the ground, output amplitude limiting and anti-static of the filtering apparatus are realized.

In a third aspect, embodiments of the present disclosure further provide a filtering device comprising the filtering apparatus according to the first aspect of embodiments of the present disclosure or the filtering apparatus according to the second aspect of embodiments of the present disclosure.

Thus, by means of the multi-stage cascaded filtering apparatus generated by encapsulating the filtering apparatus according to the first aspect of embodiments of the present disclosure or the filtering apparatus according to the second aspect of embodiments of the present disclosure in a device, multi-stage attenuation on the common-mode signals sent from the differential signal transmission circuit is performed, which has small impact on the differential signals and better improves the signal-to-noise ratio of the differential line signals in a wider bandwidth; meanwhile, the multi-stage attenuation on the common-mode signals introduced from the loads of the differential signals and the common-mode signals introduced during the transmission is also performed, which has better attenuation effect and protects the differential signal transmission circuit. In addition, multi-stage filtering on the plane noises and the common-mode signals coupled through the cable is also performed, which further improves the signal-to-noise ratio of the differential line signals, and further decreases outward radiation of the noises from the data cable by cascading to reduce the common-mode signals.

In a possible implementation of the third aspect, the filtering device comprises any possible implementations of the filtering apparatus according to the first aspect of embodiments of the present disclosure when the filtering device comprises the filtering apparatus according to the first aspect of embodiments of the present disclosure.

Thus, by encapsulating any possible implementations of the filtering apparatus according to the first aspect of embodiments of the present disclosure in a device, the functions corresponding to the possible implementations of the filtering apparatus according to the first aspect of embodiments of the present disclosure are realized.

In a possible implementation of the third aspect, the filtering device comprises any possible implementations of the filtering apparatus according to the second aspect of embodiments of the present disclosure when the filtering device comprises the filtering apparatus according to the second aspect of embodiments of the present disclosure.

Thus, by encapsulating any possible implementations of the filtering apparatus according to the second aspect of embodiments of the present disclosure in a device, the functions corresponding to the possible implementations of the filtering apparatus according to the second aspect of embodiments of the present disclosure are realized.

In a fourth aspect, embodiments of the present disclosure further provide a filtering apparatus comprising: a device encapsulating the common-mode inductors in the first aspect of the embodiments of the present disclosure or in any possible implementation of the first aspect, and other circuit in the first aspect of the embodiments of the present disclosure or in any possible implementation of the first aspect.

Thus, the fourth aspect of the embodiments of the present disclosure has the advantages of the first aspect of the embodiments of the present disclosure or any possible implementation s of the first aspect.

In a fifth aspect, embodiments of the present disclosure further provide a filtering apparatus comprising: a device encapsulating the common-mode inductors in the second aspect of the embodiments of the present disclosure or in any possible implementation of the second aspect, and other circuit in the second aspect of the embodiments of the present application or in any possible implementation of the second aspect.

Thus, the fifth aspect of the embodiments of the present disclosure has the advantages of the second aspect of the embodiments of the present disclosure or any possible implementation of the second aspect.

In a sixth aspect, embodiments of the present disclosure further provide a transmission apparatus comprising a differential cable, where both ends of the differential cable is connected to one of the following apparatus or device: the filtering apparatus according to the first aspect of embodiments of the present disclosure or in any possible implementations of the first aspect; the filtering apparatus according to the second aspect of embodiments of the present disclosure or in any possible implementations of the second aspect; the device according to the third aspect of embodiments of the present disclosure or in any possible implementations of the third aspect; the filtering apparatus according to the fourth aspect of embodiments of the present application; and the filtering apparatus according to the fifth aspect of embodiments of the present disclosure.

Thus, by means of the transmission apparatus including the filtering apparatus or the filtering device for multi-stage cascade filtering of the common-mode signal, multi-stage attenuation on the common-mode signals sent from the differential signal transmission circuit is performed, which has small impact on the differential signals and better improves the signal-to-noise ratio of the differential line signals in a wider bandwidth; meanwhile, the multi-stage attenuation on the common-mode signals introduced from the loads of the differential signals and the common-mode signals introduced during the transmission is also performed, which has better attenuation effect and protects the differential signal transmission circuit. In addition, multi-stage filtering on the plane noises and the common-mode signals coupled through the cable is also performed, which further improves the signal-to-noise ratio of the differential line signals, and further decreases outward radiation of the noises from the data cable by cascading to reduce the common-mode signals.

In a possible implementation of the sixth aspect, used between a shielding layer at the both ends of the differential cable and the ground is any of the following connection manners: no connection; connection via an inductor; and connection via a magnetic bead.

Thus, by means of no connection, connection via a inductor or connection via a magnetic bead between a shielding layer at the both ends of the differential cable and the ground, these manners realize the isolation between the shielding layer of the differential cable and the ground, and when the filtering apparatus or filtering device for multi-stage cascade filtering reduces the common-mode signals in the differential line, the common-mode noises of the ground coupled to the shielding layer of the differential cable by the ground line are reduced through the above isolation.

### BRIEF DESCRIPTION OF THE DRAWINGS

FIG. 1A is a schematic diagram of a disclosed first filtering circuit;

FIG. 1B is a schematic diagram of a disclosed second filtering circuit;

FIG. 1C is a schematic diagram of a disclosed third filtering circuit;

FIG. 2 is a structural schematic diagram of a conventional application scenario according to embodiments of the present disclosure;

FIG. 3A is a structural schematic diagram of a filtering apparatus according to a first embodiment of the present disclosure;

FIG. 3B1 is a schematic diagram of effect analysis of a practical application of the filtering apparatus according to the first embodiment of the present disclosure;

FIG. 3B2 is a schematic diagram of effect analysis of another practical application of the filtering apparatus according to the first embodiment of the present disclosure;

FIG. 3C1 is a structural schematic diagram of a specific implementation of the filtering apparatus according to the first embodiment of the present disclosure;

FIG. 3C2 is a schematic diagram of a change of an absolute value of a common-mode impedance and an absolute value of a differential-mode impedance of a common-mode inductor with frequency;

FIG. 3C3 is a schematic diagram of filtering effect of the specific implementation of the filtering apparatus according to the first embodiment of the present disclosure;

FIG. 3C4 is a schematic diagram of filtering effect of the disclosed second filtering circuit;

FIG. 3C5 is a schematic diagram of filtering effect of the disclosed third filtering circuit;

FIG. 4A is a structural schematic diagram of a filtering apparatus according to a second embodiment of the present disclosure;

FIG. 4B1 is a schematic diagram of effect analysis of a practical application of the filtering apparatus according to the second embodiment of the present disclosure;

FIG. 4B2 is a schematic diagram of effect analysis of another practical application of the filtering apparatus according to the second embodiment of the present disclosure;

FIG. 4C is a structural schematic diagram of a specific implementation of the filtering apparatus according to the second embodiment of the present disclosure;

FIG. 5A1 is a structural schematic diagram of a first variant of the filtering apparatus according to the second embodiment of the present disclosure;

FIG. 5A2 is a structural schematic diagram of a second variant of the filtering apparatus according to the second embodiment of the present disclosure;

FIG. 5A3 is a structural schematic diagram of a third variant of the filtering apparatus according to the second embodiment of the present disclosure;

FIG. 5B1 is a structural schematic diagram of a fourth variant of the filtering apparatus according to the second embodiment of the present disclosure;

FIG. 5B2 is a structural schematic diagram of a fifth variant of the filtering apparatus according to the second embodiment of the present disclosure;

FIG. 5C1 is a structural schematic diagram of a sixth variant of the filtering apparatus according to the second embodiment of the present disclosure;

FIG. 5C2 a structural schematic diagram of a seventh variant of the filtering apparatus according to the second embodiment of the present disclosure;

FIG. 5D1 is a structural schematic diagram of an eighth variant of the filtering apparatus according to the second embodiment of the present disclosure;

FIG. 5D2 is a structural schematic diagram of a ninth variant of the filtering apparatus according to the second embodiment of the present disclosure;

FIG. 5D3 is a structural schematic diagram of a tenth variant of the filtering apparatus according to the second embodiment of the present disclosure;

FIG. 5D4 is a structural schematic diagram of an eleventh variant of the filtering apparatus according to the second embodiment of the present disclosure;

FIG. 5E is a schematic diagram of a circuit structure of a combination of the first variant to the seventh variant of the filtering apparatus according to the second embodiment of the present disclosure;

FIG. 6A is a schematic diagram of a circuit structure of a filtering apparatus according to a third embodiment of the present disclosure;

FIG. 6B is a schematic diagram of values of attenuation of first common-mode signals by the filtering apparatus according to the third embodiment of the present disclosure;

FIG. 6C is a schematic diagram of values of attenuation of differential-mode signals by the filtering apparatus according to the third embodiment of the present disclosure;

FIG. 7 is a schematic diagram of a circuit structure of a filtering apparatus according to a fourth embodiment of the present disclosure;

FIG. 8 is a schematic diagram of a circuit structure of a combination of a first variant to a fifth variant of the filtering apparatus according to the fourth embodiment of the present disclosure;

FIG. 9A1 is a schematic diagram of an internal circuit structure of a device according to a first embodiment of the present disclosure;

FIG. 9A2 is a schematic diagram of an internal circuit structure of a device according to a second embodiment of the present disclosure;

FIG. 9B1 is a schematic diagram of an internal circuit structure of a device according to a third embodiment of the present disclosure;

FIG. 9B2 is a schematic diagram of an internal circuit structure of a device according to a fourth embodiment of the present disclosure;

FIG. 9C1 is a schematic diagram of a circuit structure of a combination of the first variant to the seventh variant of the device according to the second embodiment of the present disclosure;

FIG. 9C2 is a schematic diagram of a circuit structure of an eleventh variant of the device according to the second embodiment of the present disclosure;

FIG. 10 is a structural schematic diagram of an application scenario of a transmission apparatus according to an embodiment of the present disclosure; and

FIG. 11 is a structural schematic diagram of an example of the filtering apparatus according to the sixth embodiment of the present disclosure.

### DETAILED DESCRIPTION OF THE EMBODIMENTS

In the following description, reference is made to “some embodiments” which describe a subset of all possible embodiments, but it can be understood that “some embodiments” may be the same or different subset of all possible embodiments and may be combined each other without conflict.

In the following description, the terms “first\second\third” or module A, module B, module C, and the like, are used only to distinguish similar objects or to distinguish different embodiments, and do not imply a particular ordering for the objects. It should be understood that a particular sequence or order may be interchanged where permissible to enable the implementation of embodiments of the present disclosure described herein in a sequence other than that illustrated or described herein.

Unless otherwise defined, all technical and scientific terms used herein have the same meaning as commonly understood by those skilled in the art belonging to the present disclosure. The terms used herein are used only for the purpose of describing embodiments of the present disclosure and are not intended to limit the present disclosure.

Embodiments of the present disclosure are described below in conjunction with FIGS. 2-11.

A conventional application scenario of embodiments of the present disclosure is described in conjunction with FIG. 2. FIG. 2 illustrates a structure of the application scenario of embodiments of the present disclosure, which comprises: a differential signal transmission circuit 31, a differential signal receiving circuit 33, filtering circuits 32, and a differential cable 34, wherein the differential cable 34 is provided with a shielding layer, and the shielding layer is connected to the ground.

The differential signal transmission circuit 31 transmits differential-mode signals, which enter the cable 34 after common-mode signals are filtered by the left filtering circuit 32; the differential-mode signals are received after being transmitted through the differential cable 34 and are received by the differential signal receiving circuit 33 after the common-mode signals are filtered again by the right filtering circuit 32.

In some embodiments, the differential cable 34 is replaced with a cable without the shielding layer.

In some embodiments, the filtering circuit 32 may be a filtering apparatus or filtering device.

In some embodiments, the differential signal transmission circuit 31 may be a differential signal transmission device or a differential signal transmission apparatus, and the signal receiving circuit 33 may be a differential signal receiving apparatus or a differential signal receiving device.

In some embodiments, the differential signal transmission circuit 31 includes a differential signal output circuit.

In some embodiments, a differential signal driving circuit is further deployed behind the left filtering circuit 32.

The differential signal transmission circuit 31 may generate the common-mode signals to be sent to the differential signal receiving circuit 33. The differential signal receiving circuit 33 also additionally generates interfering common-mode signals, which propagate backwards via the differential cable to the differential signal transmission circuit 31. The common-mode signals may also be coupled into the differential cable and then be sent to the differential signal transmission circuit 31 or the differential signal receiving circuit 33. Noises of the ground plane may also become the common-mode signals to be sent to the differential signal transmission circuit 31 or the differential signal receiving circuit 33. For ease of description, the common-mode signals are classified in accordance with the transmission directions in which they couple into the filtering circuit. In the example of the filtering circuit of FIG. 2, the common-mode signals coming in from an input terminal of the filtering circuit 32 and transmitted toward the right are recorded as first common-mode signals, and the common-mode signals coming in from an output terminal of the filtering circuit 32 and transmitted toward the left are recorded as second common-mode signals. The embodiments of the present disclosure are used to improve the filtering performance for both the first common-mode signals and the second common-mode signals in the differential line.

Filtering apparatuses according to embodiments of the present disclosure are described below in conjunction with the figures.

### [Filtering Apparatus According to a First Embodiment]

The filtering apparatus according the first embodiment uses an apparatus consisting of two common-mode inductors in series and a differential-mode inductor connected between a differential line between the two common-mode inductors and the ground, which forms a two-stage cascaded filtering of the common-mode signals and has a better filtering effect.

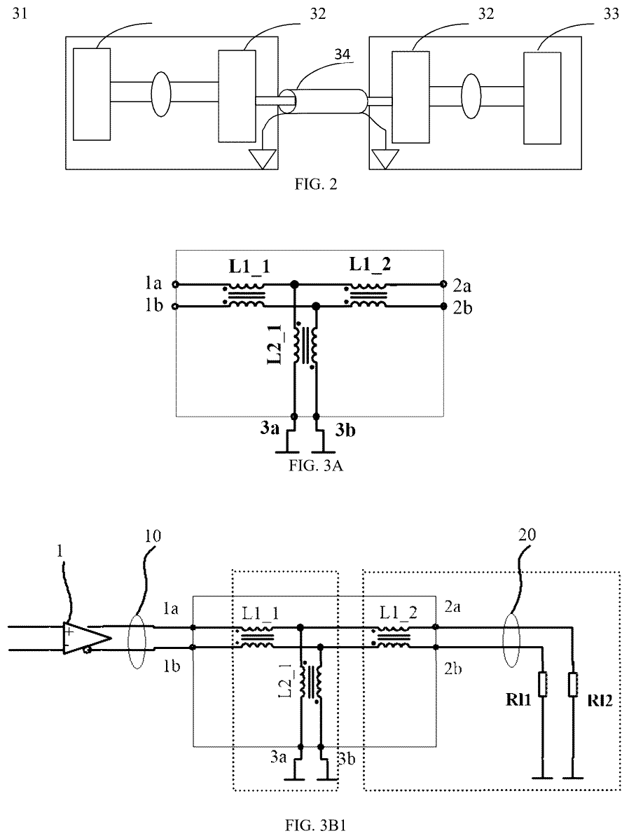

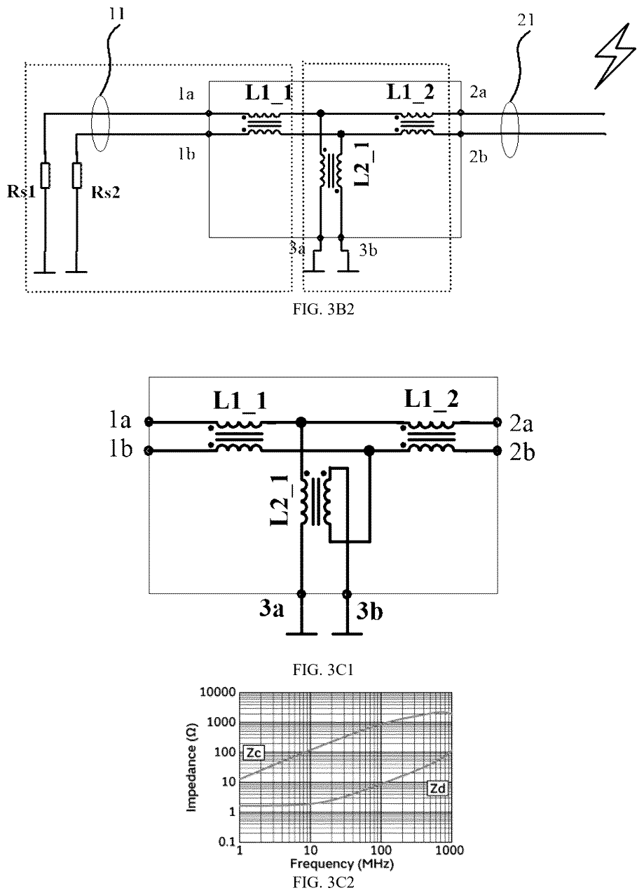

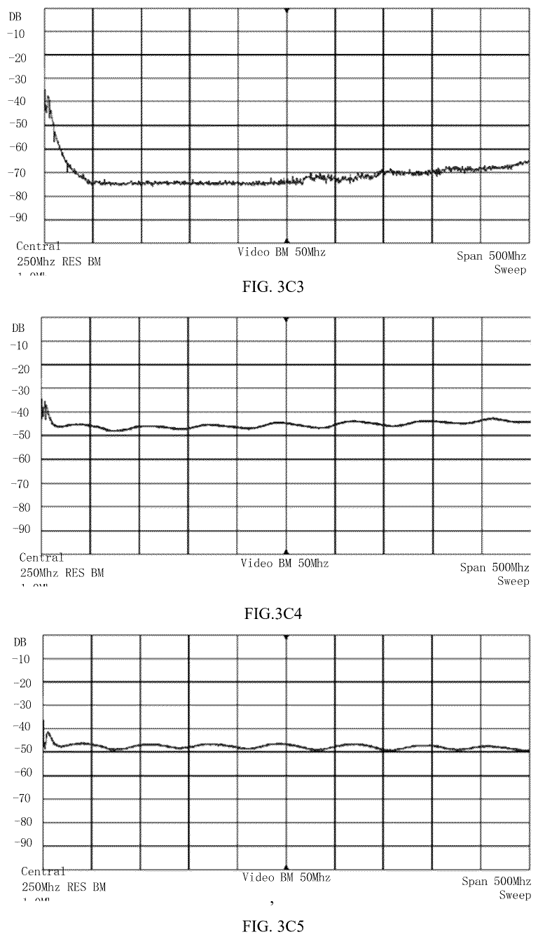

FIG. 3A illustrates a structure of the filtering apparatus according to the first embodiment, which comprises a common-mode inductor L1_1, a differential-mode inductor L2_1, and a common-mode inductor L1_2 connected in a sequence, wherein magnetic fluxes generated by the common-mode signals of two coils of each common-mode inductor enhance each other, and the magnetic fluxes generated by the common-mode signals of two coils of the differential-mode inductor counteract each other. The two coils of the common-mode inductor L1_1 are connected in series to input terminals 1a and 1b of the apparatus, respectively. The two coils of the differential-mode inductor L2_1 are connected between two branches of the differential line between L1_1 and L1_2 and ground terminals 3a and 3b, respectively. The two coils of the common-mode inductor L1_2 are connected in series between the two coils of the common-mode inductor L1_1 and output terminals 2a and 2b of the apparatus, respectively.

Absolute values of common-mode impedances of the common-mode inductor L1_1 and the common-mode inductor L1_2(in order to express more intuitive and more convenient, a modulus value of the impedance of the inductor, a capacitor or a device containing inductors and capacitors herein are also called the absolute value) are much larger than the absolute value of the common-mode impedance of the differential-mode inductor L2_1. The absolute value of the differential-mode impedance of the differential-mode inductor L2_1 is much larger than the absolute values of the differential-mode impedances of the common-mode inductor L1_1 and the common-mode inductor L1_2.

Exemplarily, the two coils of each common-mode inductor of FIG. 3A are wound in the same direction, and if the two coils are both wound in the clockwise direction or the counterclockwise direction, the current directions of the common-mode signals in the two coils are also the clockwise direction or the counterclockwise direction. When the two coils of each common-mode inductor are wound in different directions, the current directions of their common-mode signals are also different. If one of the two coils is wound in the clockwise direction and the other is wound in the counterclockwise direction, the current direction of the common-mode signals in one of the two coils will be the clockwise direction, and the current direction of the common-mode signals in the other will be the counterclockwise direction.

Exemplarily, the two coils of the differential-mode inductor of FIG. 3A are wound in different directions, and when one of the two coils is wound in a clockwise direction and the other is wound in a counterclockwise direction, the current directions of the common-mode signals in the two coils both are either the clockwise direction or the counterclockwise direction. When the two coils of the differential inductor are wound in the same direction, the current direction of the common-mode signals in one of the two coils is the clockwise direction and the current direction of the common-mode signals in the other is the counterclockwise direction.

The components of the filtering apparatus according to the second embodiment are passive components, the input terminals and the output terminals of the apparatus are interchangeable and work on the same principle. The following descriptions assume that the input terminals are on the left side of the figures and the output terminals are on the right side of the figures.

FIG. 3B1 is a diagram of effect analysis of the practical application of the circuit shown in FIG. 3A, where the first common-mode signals are transmitted from left to right. The first common-mode signals are sent out from a leftmost differential signal output circuit 1, pass through the cable 10 to reach the input terminals 1a and 1b of the filtering apparatus according to the first embodiment, and then successively pass through a first filtering module (the circuit in the dashed box on the left of FIG. 3B1) and the common-mode inductors L1_2 of a second filtering module (the circuit in the dashed box on the right of FIG. 3B1) of the filtering apparatus according to the first embodiment to reach the output terminals 2a and 2b of the filtering apparatus according to the first embodiment, and finally pass through the cable 20 to reach a load circuit (whose loads on the two branches of the differential line are RI1 and RI2, constituting a total load resistance RL).

The first filtering module comprises the common-mode inductor L1_1 and the differential mode inductor L2_1, and the second filtering module comprises the common-mode inductor L1_2 and the load impedances RI1 and RI2 connected in series. L2_1 of the first filtering module is connected in parallel with the second filtering module.

It is assumed that the common-mode impedances of L1_1, L1_2 and L2_1 are Z1_{c}, Z3_{c} and Z22_{c}, the total impedance composed of the load impedances RI1 and RI2 is RL, output impedance of the differential signal output circuit 1 is Rs (the output impedances on the two branches of the differential line are Rs1 and Rs2, which compose the total output resistance Rs), the common-mode impedance of the circuit in which L2_1 of the first filtering module and the second filtering module are connected in parallel is Z4_{c}, attenuation of the first common-mode signals by the first filtering module is G1L1_{c}, attenuation of the first common-mode signals by the second filtering module is G1L2_{c}, and attenuation of the first common-mode signals by the filtering apparatus according to the first embodiment is G1L_{c}, then there is:

$$G 1 {L}_{c} = G 1 L {1}_{c} * G 1 L {2}_{c} ,$$

wherein,

$$G 1 L {2}_{c} = {\vert \frac{R L}{R L + Z {3}_{c}} \vert}^{2} ,$$

$$G 1 L {1}_{c} = {\vert \frac{Z {4}_{c}}{Z {1}_{c} + R s + Z {4}_{c}} \vert}^{2} = {\vert \frac{1}{\frac{Z {1}_{c} + Rs}{Z {4}_{c}} + 1} \vert}^{2} , and$$

$$Z {4}_{c} = \frac{1}{\frac{1}{Z {2}_{c}} + \frac{1}{Z {3}_{c} + RL}} .$$

Because the absolute value of Z3_{c} is much larger than RL, G1L2_{c} may be approximated as:

$$G 1 L {2}_{c} \approx {\vert \frac{R L}{Z {3}_{c}} \vert}^{2} .$$

And because the absolute value of Z3_{c} is much greater than RL and the absolute value of Z3_{c} is much greater than the absolute value of Z2_{c}, then Z4_{c} may be approximated as:

Z4_{c}≈Z2_{c}.

And because the absolute value of Z1_{c} is much larger than Rs and Z2_{c} and the absolute value of Z4_{c} is approximately equal to the absolute value of Z2_{c}, then GL1_{c} may be approximated as:

$$G 1 L {1}_{c} \approx {\vert \frac{Z {2}_{c}}{Z {1}_{c}} \vert}^{2} .$$

The attenuation of the first common-mode signals by the filtering apparatus according to the first embodiment is G1L_{c}, which may be approximated as:

$$G 1 {L}_{c} \approx {\vert \frac{Z {2}_{c}}{Z {1}_{c}} \vert}^{2} * {\vert \frac{R L}{Z {3}_{c}} \vert}^{2} ,$$

When the common-mode inductors L1_1 and L1_2 are the same common-mode inductors, Z1_{c} is the same as Z3_{c}, then G1L_{c} may be approximated as:

$$G 1 {L}_{c} \approx {\vert \frac{Z {2}_{c}}{Z {1}_{c}} \vert}^{2} * {\vert \frac{R L}{Z {1}_{c}} \vert}^{2} .$$

If decibel (d B) is used as the unit of the attenuation, there is:

$$G 1 {L}_{c} \approx 20 * log ( \vert \frac{Z {2}_{c}}{Z {1}_{c}} \vert ) + 20 * log ( \vert \frac{R L}{Z {1}_{c}} \vert ) . \qquad ( 1 )$$

Because the absolute value of Z1_{c} is much greater than the absolute value of Z2_{c} and RL, it is known from the above equation that G1Lc is very small, i.e., the attenuation of the first common-mode signals is larger. It should be noted that the logarithmically expressed attenuation value in embodiments of the present disclosure is negative, and the larger the absolute value thereof is, the larger the attenuation is.

It is assumed that the differential-mode impedances of L1_1, L1_2 and L2_1 are Z1_{d}, Z3_{d} and Z2_{d}, the total impedance of the load forming by the load impedances RI1, RI2 for the differential-mode signals is also RL, the impedance of the differential signal output circuit 1 for the differential-mode signals is also Rs, the differential-mode impedance of the circuit in which the L2_1 of the first filtering module and the second filtering module are connected in parallel is Z4_{d}, the attenuation of the differential-mode signals by the first filtering module is G1L1_{d}, the attenuation of the differential-mode signals by the second filtering module is G1L2_{d}, and the attenuation of the differential-mode signals by the whole apparatus is G1L_{d}, and then there is:

$$G 1 {L}_{d} = G 1 L {1}_{d} * G 1 L {2}_{d} ,$$

wherein,

$$G 1 L {2}_{d} = {\vert \frac{R L}{R L + Z {3}_{d}} \vert}^{2} ,$$

$$G 1 L {1}_{d} = {\vert \frac{Z {4}_{d}}{Z {1}_{d} + Z {4}_{d} + Rs} \vert}^{2} = {\vert \frac{1}{\frac{Z {1}_{d} + Rs}{Z {4}_{d}} + 1} \vert}^{2} , and$$

$$Z {4}_{d} = \frac{1}{\frac{1}{Z {2}_{d}} + \frac{1}{Z {3}_{d} + RL}} .$$

Because the absolute value of Z2_{d} is much greater than the absolute value of Z3_{d}, then Z4a may be approximated as:

$$Z {4}_{d} \approx Z {3}_{d} + RL ,$$

then G1L1_{d} may be approximated as:

$$G 1 L {1}_{d} \approx {\vert \frac{Z {3}_{0} + R L}{Z {1}_{0} + R s + Z {3}_{d} + R L} \vert}^{2} ,$$

then G1L_{d} may be approximated as:

$$G 1 {L}_{d} \approx {\vert \frac{R L}{Z {1}_{d} + R s + Z {3}_{d} + R L} \vert}^{2} .$$

When the common-mode inductors L1_1 and L1_2 are the same common-mode inductors, Z1_{c} is the same as Z3_{c}, and then G1L_{c} may be approximated as:

$$G 1 {L}_{d} \approx {\vert \frac{R L}{2 * Z {1}_{d} + R s + R L} \vert}^{2} ,$$

and if decibel (dB) is used as the unit of the attenuation, then there is:

$$G 1 {L}_{d} \approx 20 * log \frac{R L}{2 * Z {1}_{d} + R s + R L} . \qquad ( 2 )$$

And because maximum value of the absolute value of Z1_{d} and the absolute value of Z3_{d} is comparable to RL and Rs, G1L_{d} is close to 0, and the attenuation is small.

FIG. 3B2 is a diagram of effect analysis of another practical application of the circuit shown in FIG. 3A, where the second common-mode signals are transmitted from right to left. The second common-mode signals are introduced from a rightmost cable 21 (or a connector or a wiring) or load, and successively pass through a third filtering module (the circuit in the dashed box on the right side of FIG. 3B2) and the common-mode inductor L1_1 in a fourth filtering module (the circuit in the dashed box on the left side of FIG. 3B2), reach the terminals 1a, 1b, and finally pass through the cable 11 to reach the differential signal output circuit 1.

The third filtering module comprises the common-mode inductor L1_2 and the differential-mode inductor L2_1, and the fourth filtering module comprises the common-mode inductor L1_1 and device impedances Rs1 and Rs2 connected in series.

Considering the third filtering module and the fourth filtering module in FIG. 3B2 as the first filtering module and the second filtering module in FIG. 3B1, respectively, and the load impedance being Rs, it may be obtained using the method of FIG. 3B1 described above that, the attenuation of the second common-mode signals by the filtering apparatus according to the first embodiment is G1R_{c}, which may be approximated as:

$$G 1 {R}_{c} \approx {\vert \frac{Z {2}_{c}}{Z {1}_{c}} \vert}^{2} * {\vert \frac{R s}{Z {1}_{c}} \vert}^{2} .$$

If decibel (d B) is used as the unit of the attenuation, then there is:

$$G 1 {R}_{c} \approx 20 * log ( \vert \frac{Z {2}_{c}}{Z {1}_{c}} \vert ) + 20 * log ( \vert \frac{R s}{Z {1}_{c}} \vert ) . \qquad ( 3 )$$

Because the absolute value of Z1_{c} is much larger than the absolute value of Z2_{c} and Rs, G1Rc is very small, and the attenuation of the second common-mode signals is greater, which protects the differential signal transmission circuit.

Since the first common-mode signals are noises generated by the differential signal transmission circuit (which is the differential signal transmission circuit 31 in FIG. 2) in FIG. 3B1 containing the differential signal output circuit 1, or external interference coupled in through the cable 10 or ground plane noises, and the second common-mode signals are noises generated by the load of the differential signals in FIG. 3B2, or external interference coupled in through the cable 21 and ground plane noises, the filtering apparatus according to the first embodiment has a cascaded attenuation effect on the common-mode signals such as the noises generated by the differential signal transmission circuit (which is the differential signal transmission circuit 31 in FIG. 2) containing the differential signal output circuit 1, the noises generated by the load of the differential signals (the differential signal receiving circuit 33 in FIG. 2), the interference coupled in through the cable or the ground plane noises, and the filtering effect is better.

The filtering apparatus according to the present embodiment also effectively reduces the outward electromagnetic radiation of the cable by suppressing the common-mode signals generated by the differential signal transmission circuit (which is the differential signal transmission circuit 31 in FIG. 2) containing the differential signal output circuit 1.

In summary, by utilizing the characteristics of high common-mode impedance and low differential-mode impedance of the common-mode inductor and the characteristics of low common-mode impedance and high differential-mode impedance of the differential-mode inductor, the two common-mode inductors connected in series and the differential-mode inductor connected in parallel between the two inductors in the filtering apparatus according to the first embodiment form a cascaded filtering apparatus to perform a two-stage attenuation on the common-mode signals generated by the differential signal transmission circuit, which has good attenuation effect and little impact on the differential-mode signals, and better improves the signal-to-noise ratio of the differential line signal in a wide bandwidth. Meanwhile, the cascaded filtering apparatus also performs the two-stage attenuation on the common-mode signals generated by the load of the differential line, which protects the differential signal transmission circuit. The common-mode input impedance of the input terminals of the apparatus according to the first embodiment is large, which will not cause the differential signal transmission circuit to heat up and work abnormally due to excessive load. In addition, the ground plane noises and the common-mode signals coupled in through the cable can be effectively filtered out, and outward radiation of the noises can also be decreased by reducing the common-mode signals on the data cable.

### [Specific Implementation of the Filtering Apparatus According to the First Embodiment]

In the present specific implementation, the apparatus in FIG. 3C1 is taken as an example, wherein the two coils in the used differential-mode inductor are wound in the same direction, and the common-mode inductors and the differential-mode inductor are the same chokes, all of which are the same as the common-mode inductor L1_1 in FIG. 3B1, so as to make the circuit components of the whole apparatus simple and standardized.

Therefore, in the present specific implementation, the common-mode impedances of the common-mode inductors are the same as the differential-mode impedance of the differential-mode inductor, which are denoted by Z_{c}, and the differential-mode impedances of the common-mode inductors are the same as the common-mode impedance of the differential-mode inductor, which are denoted by Z_{d}.

Again, it is assumed that the load impedance of the load connected to the right side of the apparatus in FIG. 3C1 is RL, and the impedance of an apparatus for inputting differential signals on the left side is Rs. Using the method in [Filtering apparatus according to a first embodiment], the attenuation G1L_{c} of the first common-mode signals, the attenuation G1L_{d} of the differential-mode signals and the attenuation G1Rc of the second common-mode signals by the apparatus according to the present specific implementation are calculated with the unit in dB, and equations similar to the equations (1), (2) and (3) may be obtained, wherein the common-mode impedances of the common-mode inductors and the differential-mode impedance of the differential-mode inductor are denoted by Z_{c}, and the differential-mode impedances of the common-mode inductors and the common-mode impedance of the differential-mode inductor are denoted by Z_{d}. It may then be obtained that the attenuation G1L_{c} of the first common-mode signals by the apparatus according to the present specific implementation is:

$$G 1 {L}_{c} \approx 20 * log ( \vert \frac{{Z}_{d}}{{Z}_{c}} \vert ) + 20 * log ( \vert \frac{R L}{{Z}_{c}} \vert ) , \qquad ( 4 )$$

the attenuation G1L_{d} of the differential-mode signals by the apparatus according to the present specific implementation is:

$$G 1 {L}_{d} \approx 20 * log \frac{R L}{2 * {Z}_{d} + R s + R L} , \qquad ( 5 )$$

the attenuation G1R_{c} of the second common-mode signals by the apparatus according to the present specific implementation is:

$$G 1 {R}_{c} \approx 20 * log ( \vert \frac{{Z}_{d}}{{Z}_{c}} \vert ) + 20 * log ( \vert \frac{R S}{{Z}_{c}} \vert ) . \qquad ( 6 )$$

Exemplarily, FIG. 3C2 illustrates numerical comparison between the common-mode impedance Z_{c} and the differential mode impedance Z_{d} of a certain single wideband common-mode inductor. The absolute value of Z_{c} is much larger than the absolute value of Z_{d}. The absolute value at the maximum value of Z_{d} is approximate to RL and Rs. Suppose that the absolute value at the maximum value of Z_{d} is equal to RL and RL is equal to Rs. By placing them into the equations (4), (5) and (6), it may be obtained that in the wideband range, the attenuations of the first common-mode signals and the second common-mode signals by the present specific implementation are great, and the attenuation of the differential-mode signals is small.

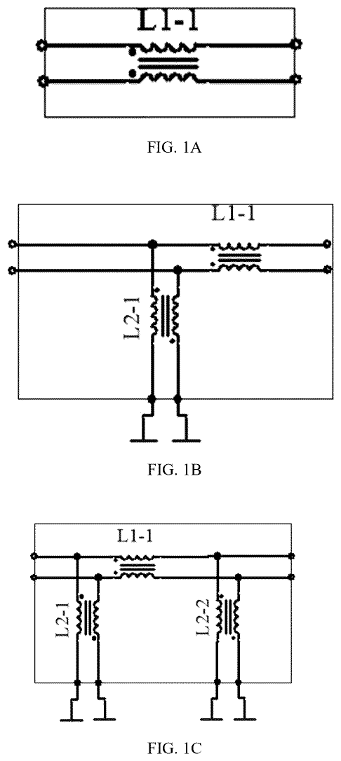

It may be seen by comparing the differential filtering apparatus disclosed in FIG. 1A, FIG. 1B and FIG. 1C that, the apparatuses in FIG. 1B and FIG. 1C have a better filtering effect than that in FIG. 1A. The following takes FIG. 1B and FIG. 1C as examples to compare the filtering effect of the present specific implementation with that of the disclosed technologies.

For the sake of comparison, the differential-mode inductors in FIGS. 1C and 1B are the same as those in the present implementation and use the choke in which the two coils are wound in the same direction, i.e., have the same choke as the common-mode inductors, and their connection manner also uses the connection manner of the present specific implementation.

FIG. 3C3 illustrates a diagram of the measured filtering effect of the present specific implementation, FIG. 3C4 illustrates a diagram of the measured filtering effect of FIG. 1B, and FIG. 3C5 illustrates a diagram of the measured filtering effect of FIG. 1C. It can be seen from the comparison of the effects shown in FIG. 3C3 and FIG. 3C4 or FIG. 3C5 that, the filtering effect of the present specific implementation is 20 dB higher than that of the disclosed differential filtering apparatus in FIG. 1B or 1C. It is verified from the actual test that the filtering effect of the present specific implementation is better.

In summary, the present specific implementation has two-stage attenuation for the common-mode signals in both positive and negative directions, which has good attenuation effect and high operating bandwidth. The common-mode input impedance of the input terminals of the present specific implementation is large, which will not cause the differential-mode signal transmission device to heat up and work abnormally due to excessive load.

### [Filtering Apparatus According to a Second Embodiment]

The filtering apparatus according to the second embodiment has multiple circuit combinations connected in a sequence after the filtering apparatus according to the first embodiment to form a multi-stage cascaded filtering of the common-mode signals, wherein each of the multiple circuit combinations comprises a common mode inductor and a differential mode inductor.

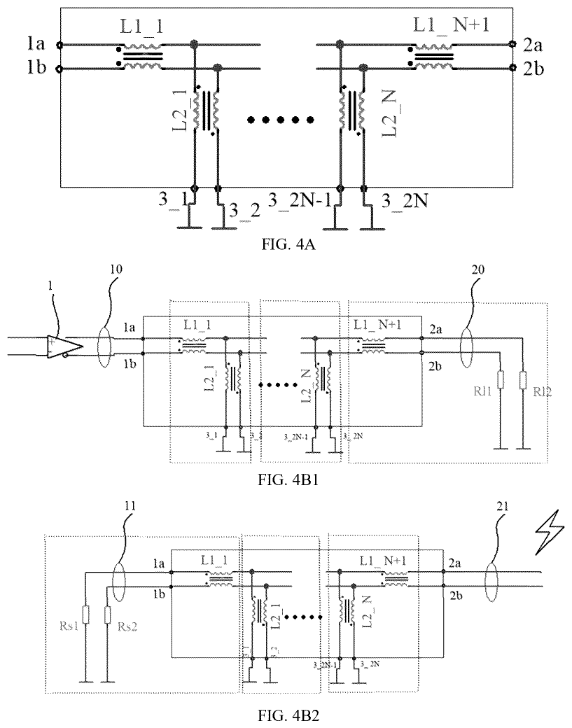

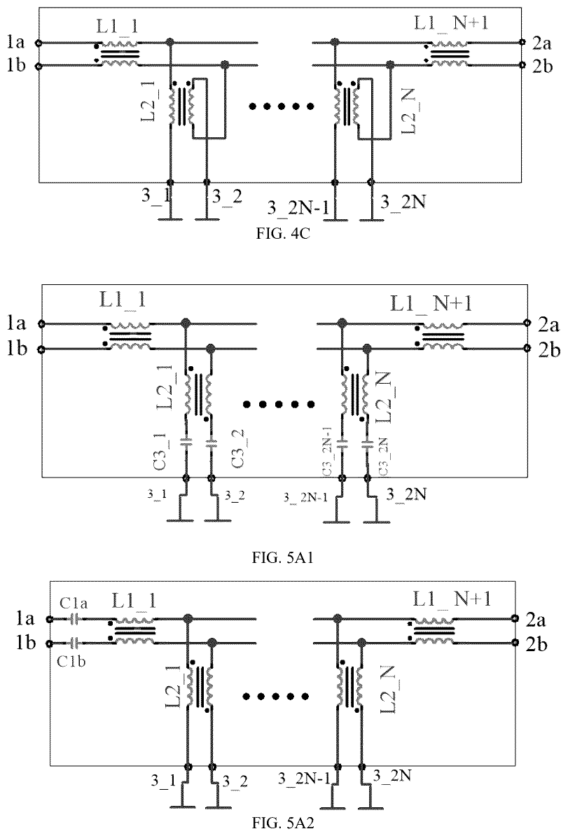

FIG. 4A illustrates a structure of the filtering apparatus according to the second embodiment, which comprises N−1 common-mode inductors and N−1 differential-mode inductors connected in a sequence after the filtering apparatus according to the first embodiment. The N−1 common-mode inductors are sequentially connected in series to the differential line and numbered as L1_3 to L1_N+1, wherein the two coils of each common-mode inductor are connected in series to respective branches of the differential line, respectively. The N−1 differential-mode inductors are sequentially connected in parallel between the differential line and the ground and numbered as L2_2 to L2_N, wherein the two coils of each differential-mode inductor each are connected between a branch of the differential line and the ground.

Exemplarily, the two coils of each common-mode inductor of FIG. 4A are wound in the same direction. If the two coils are wound in the clockwise direction or the counterclockwise direction, the current directions of the common-mode signals in the two coils both are also the clockwise direction or the counterclockwise direction. When the two coils of each common-mode inductor are wound in different directions, the current directions of the common-mode signal are also different. If one of the two coils is wound in the clockwise direction and the other is wound in the counterclockwise direction, the current direction of the common-mode signals in one of the two coils will be the clockwise direction, and the current direction of common-mood signals in the other will be the counterclockwise direction.

Exemplarily, the two coils of the differential-mode inductor of FIG. 4A are wound indifferent directions, and if one of the two coils is wound in a clockwise direction and the other is wound in a counterclockwise direction, then the current directions of the common-mode signals in the two coils are both the clockwise direction or both the counterclockwise direction. When the two coils of the differential inductor are wound in the same direction, the current direction of the common-mode signals in one of the two coils thereof is the clockwise direction and the current direction of common-mood signals in the other is the counterclockwise direction.

The components of the apparatus according to the second embodiment are passive components, the input terminals and the output terminals of the apparatus are interchangeable and work on the same principle. The following descriptions assume that the input terminals are on the left side of the figures and the output terminals are on the right side of the figures.

In a practical application, the common-mode inductors L1_i (i=1, 2, . . . , N+1) may be the same or different, and the differential-mode inductors L2_i (i=1, 2, . . . , N) may be the same or different, but the analytical method is the same. All of the common-mode inductors L1_i and the differential mode inductors L2_i fall into the scope of protection of the present disclosure regardless of whether they are the same or different.

For ease of description, it is assumed that the common-mode inductors L1_i are the same, wherein their common-mode impedances are Z1_{c}, and their differential-mode impedances are Z1a. It is assumed that the differential-mode inductors L2_i are the same, wherein their common-mode impedances are the same and Z2_{c} and their differential-mode impedances are Z2_{d}. In the wideband range, the absolute value of Z1_{c} is much larger than Z2_{c}, and the absolute value of Z2_{d} is much larger than the absolute value of Z1d.

FIG. 4B1 is a diagram of effect analysis of the practical application of the circuit shown in 4A (the case where the common-mode signals are transmitted from left to right). The common-mode signals are sent out from the leftmost differential signal output circuit 1, pass through the cable 10 to reach the terminals 1a and 1b, sent outward from the terminals 2a and 2b after being filtered by the apparatus according to the second embodiment, and pass through the cable 20 to reach the load of the differential signals. The common-mode signals successively pass through respective first filtering modules B_i (i=1, 2, . . . , N) (the circuits in the N dashed boxes on the left side of FIG. 4B1) and a second filtering module B (the circuit in the dashed box on the right of FIG. 4B1). The first filtering modules B_i are each composed of a common-mode inductor L1_i and a differential-mode inductor L2_i, and the second filtering module B is composed of a common-mode inductor L1_N+1 and load impedances RI1, RI2. The differential-mode inductor L2_i of each of the first filtering modules B_i is connected in parallel with the filtering module of the corresponding next stage and the paralleled impedance is Z4_{ic}.

Similarly, it is assumed that the total impedance composed of the load impedances RI1 and RI2 is RL, the output impedance of the differential signal output circuit 1 is Rs, the attenuation of the common-mode signals by each first filtering module B_i is G2L1_{ic}, the attenuation of the common-mode signals by the second filtering module B is G2L2_{c}, and the attenuation of the common-mode signals by the whole apparatus is G2L_{c}, and then there is:

$$G 2 {L}_{c} = {\prod }_{i = 1}^{N} G 2 L {1}_{i c} * G 2 L {2}_{c}$$

$$wherein ,$$

$$G 2 L {2}_{c} = {\vert \frac{R L}{R L + Z {1}_{c}} \vert}^{2} ,$$

$$G 2 L {1}_{i c} = {\vert \frac{Z {4}_{i c}}{Z {1}_{c} + Z {4}_{i c}} \vert}^{2} = {\vert \frac{1}{\frac{Z {1}_{c}}{Z {4}_{i c}} + 1} \vert}^{2} , i = 2 , 3 , … , N ,$$

$$G 2 L {1}_{1 c} = {\vert \frac{Z {4}_{1 c}}{Z {1}_{c} + R S + Z {4}_{1 c}} \vert}^{2} = {\vert \frac{1}{\frac{Z {1}_{c} + Rs}{Z {4}_{1 c}} + 1} \vert}^{2} ,$$

$$Z {4}_{i c} = \frac{1}{\frac{1}{Z {2}_{c}} + \frac{1}{Z {1}_{c} + Z {4}_{( i + 1 ) c}}} ,$$

wherein, Z4_{(N+1) c} is equal to RL.

Because the absolute value of Z1_{c} is much larger than RL, then G2L2_{c} may be approximated as:

$$G 2 L {2}_{c} \approx {\vert \frac{R L}{Z {1}_{c}} \vert}^{2} .$$

And because the absolute value of Z1_{c} is much greater than RL, and the absolute value of Z1_{c} is much larger than the absolute value of Z2_{c}, it may be approximated as:

$$Z {4}_{i c} \approx Z {2}_{c} , i = 2 , 3 , … , N .$$

And because the absolute value of Z1_{c} is much larger than Z2_{c} and RS, and the absolute value of Z4_{ic} is approximately equal to the absolute value of Z2_{c}, then G2L1_{ic} may be approximated as:

$$G 2 L {1}_{i c} \approx {\vert \frac{Z {2}_{c}}{Z {1}_{c}} \vert}^{2} , i = 2 , 3 , … , N .$$

The attenuation of the first common-mode signals by the apparatus according to the second embodiment is G2L_{c}, which may be approximated as:

$$G 2 {L}_{c} \approx {\prod }_{i = 1}^{N} {\vert \frac{Z {2}_{c}}{Z {1}_{c}} \vert}^{2} * {\vert \frac{R L}{Z {1}_{c}} \vert}^{2} .$$

If decibel (d B) is used as the unit of the attenuation, then there is:

$$G 2 {L}_{c} \approx 20 * N * log ( \vert \frac{Z {2}_{c}}{Z {1}_{c}} \vert ) + 20 * log ( \vert \frac{R L}{Z {1}_{c}} \vert ) . \qquad ( 7 )$$

Because the absolute value of Z1_{c} is much greater than the absolute

$$- 20 * ( N - 1 ) * log ( \vert \frac{Z {2}_{c}}{Z {1}_{c}} \vert )$$

than that of G1L_{c} of the filtering apparatus according to the first embodiment, that is, the attenuation value of the first common-mode signals is increased by at least

$$- 20 ⋆ ( N - 1 ) * log ( \vert \frac{Z {2}_{c}}{Z {1}_{c}} \vert ) .$$

It is assumed that the differential-mode impedance of the circuit in which L2_i of each first filtering module B_i is connected in parallel with the filtering module of the next stage is Z4_{id}, the attenuation of the differential-mode signals by each first filtering module B_i is G2L1_{id}, the attenuation of the differential-mode signals by the second filtering module Bis G2L2ₐ, and the attenuation of the differential-mode signals by the whole apparatus is G2L_{d}, and then there is:

$$G 2 {L}_{d} = {\prod }_{i = 1}^{N} G 2 L {1}_{i d} * G 2 L {2}_{d} ,$$

$$wherein ,$$

$$G 2 L {2}_{d} = {\vert \frac{R L}{R L + Z {1}_{d}} \vert}^{2} ,$$

$$G 2 L {1}_{1 d} = {\vert \frac{Z {4}_{1 d}}{Z {1}_{d} + Rs + Z {4}_{1 d}} \vert}^{2} ,$$

$$G 2 L {1}_{i d} = {\vert \frac{Z {4}_{id}}{Z {1}_{d} + Z {4}_{id}} \vert}^{2} , i = 2 , 3 , … , N ,$$

$$Z {4}_{i d} = \frac{1}{\frac{1}{Z {2}_{d}} + \frac{1}{Z {1}_{d} + Z {4}_{( i + 1 ) d}}} ,$$

wherein, Z4_{(N+1)d} is equal to RL.

Because the absolute value of Z2_{d} is much larger than the absolute values of Z1_{d} and RL, it may be approximated as:

$$Z {4}_{i d} \approx ( N - i + 1 ) * Z {1}_{d} + RL , i = 2 , 3 , … , N ,$$

then it may be approximated as:

$$G 2 {L}_{d} \approx {\vert \frac{R L}{( N + 1 ) * Z {1}_{d} + R S + R L} \vert}^{2} .$$

If decibel (d B) is used as the unit of the attenuation, then there is:

$$G 2 {L}_{d} \approx 20 * log \vert \frac{R L}{( N + 1 ) * Z {1}_{d} + R S + R L} \vert . \qquad ( 8 )$$

Because the absolute values of RL, RS and Z1_{d} are comparable, the attenuation of the differential-mode signals by the apparatus according to the second embodiment is controllable.

FIG. 4B2 is a diagram of effect analysis of another practical application of the circuit shown in FIG. 4A, wherein the second common-mode signals are transmitted from right to left. The second common-mode signals are introduced from the rightmost cable (or a connector or a wiring) 21 or a load, successively pass through the third filtering module B_i, i=1, 2, . . . , N (the circuits in the N dashed boxes on the right side of FIG. 4B2) and L1_1 in the fourth filtering module B (the circuit in the dashed box on the left side of FIG. 4B2), reach the terminals 1a and 1b, and finally pass through the cable 11 to reach the differential signal output circuit 1, wherein the differential signal output circuit 1 is denoted with device impedances RS1 and RS2 (the combination of Rs1 and Rs2 is Rs).

The third filtering modules B_i each consist of a common-mode inductor L1_N-i+2 and a differential-mode inductor L2_N-i+1. The fourth filtering module consists of a common-mode inductor L1_1 and device impedances Rs1 and Rs2 in series.

Considering the third filtering modules B_i in FIG. 4B2 as the first filtering modules B_i in FIG. 4B1, and the fourth filtering module in FIG. 4B2 as the second filtering module B in FIG. 4B1, it may be obtained using the method of FIG. 4B1 described above that, the attenuation of the second common-mode signals by the apparatus according to the second embodiment is G2R_{c}, which may be approximated as:

$$G 2 {R}_{c} \approx {\prod }_{i = 1}^{N} {\vert \frac{Z {2}_{c}}{Z {1}_{c}} \vert}^{2} * {\vert \frac{R S}{Z {1}_{c}} \vert}^{2} .$$

If decibel (d B) is used as the unit of the attenuation, then there is:

$$G 2 {R}_{c} \approx 20 * N * log ( \vert \frac{Z {2}_{c}}{Z {1}_{c}} \vert ) + 20 * log ( \vert \frac{R S}{Z {1}_{c}} \vert ) . \qquad ( 9 )$$

Because the absolute value of Z1_{c} is much greater than the absolute value of Z2_{c} and RS, the absolute value of G2R_{c} is

$$- 20 * ( N - 1 ) * log ( \vert \frac{Z {2}_{c}}{Z {1}_{c}} \vert )$$

greater than that of G1R_{c} of the filtering apparatus according to the first embodiment, that is, the attenuation of the second common-mode signals is at least increased by

$$- 20 * ( N - 1 ) * log ( \vert \frac{Z {2}_{c}}{Z {1}_{c}} \vert ) ,$$

which protects the differential signal transmission circuit.

In summary, by utilizing the characteristics of high common-mode impedance and low differential-mode impedance of the common-mode inductor and low common-mode impedance and high differential-mode impedance of the differential-mode inductor, the filtering apparatus according to the second embodiment utilizes a multi-stage cascaded filtering apparatus which has at least three common-mode inductors connected in series and in which every two common-mode inductors are connected in parallel with one differential-mode inductor, to perform multi-stage attenuation on the common-mode signals sent from the differential signal transmission circuit, which further improves attenuation effect on basis of the filtering apparatus according to the first embodiment, has little impact on the differential-mode signals, and better improves the signal-to-noise ratio of the differential line signals in a wider bandwidth. Meanwhile, it acts on and also performs the multi-stage attenuation on the common-mode signals introduced from the load of the differential signals and the common-mode signals introduced during the transmission, which has better attenuation effect and protects the differential signal transmission circuit. In addition, it also performs multi-stage filtering on the plane noises and the common-mode signals coupled through the cable, which further improves the signal-to-noise ratio of the differential line signals, and further decreases outward radiation of the noises from the data cable by cascading to reduce the common-mode signals.

### [Specific Implementation of the Filtering Apparatus According to the Second Embodiment]

In the present implementation, the apparatus in FIG. 4C is taken as an example, wherein the two coils in the used differential-mode inductor are wound in the same direction, and the common-mode inductors and the differential-mode inductor are the same chokes, all of which are the same as the common-mode inductor L1_1 in FIG. 4A, so as to make the circuit components of the whole apparatus simple and standardized.

Therefore, in the present specific implementation, the common-mode impedances of the common-mode inductors are the same as the differential-mode impedance of the differential-mode inductor, which are denoted by Z_{c} again, and the differential-mode impedances of the common-mode inductors are the same as the common-mode impedance of the differential-mode inductor, which are denoted by Z_{d} again.

Again, it is assumed that the load impedance of the load connected to the right side of the apparatus in FIG. 4C is RL, and the impedance of an apparatus for inputting differential signals on the left side is Rs. Using the method in [Filtering apparatus according to a second embodiment], the attenuation G2L_{c} of the first common-mode signals by the apparatus according to the present specific implementation, the attenuation G2L_{d} of the differential-mode signals by the apparatus and the attenuation G2R_{c} of the second common-mode signals by the apparatus are calculated with the unit in dB, and equations similar to the equations (7), (8) and (9) may be obtained, wherein the common-mode impedances of the common-mode inductors and the differential-mode impedance of the differential-mode inductor are denoted by Z_{c}, and the differential-mode impedances of the common-mode inductors and the common-mode impedance of the differential-mode inductor are denoted by Z_{d}. It may then be obtained that the attenuation G2L_{c} of the first common-mode signals by the apparatus according to the present specific implementation is:

$$G 2 {L}_{c} \approx 20 * N * log ( \vert \frac{{Z}_{d}}{{Z}_{c}} \vert ) + 20 * log ( \vert \frac{R L}{{Z}_{c}} \vert ) , \qquad ( 10 )$$

the attenuation G2L_{d} of the differential-mode signals by the apparatus according to the present specific implementation is:

$$G 2 {L}_{d} \approx 20 * log \frac{R L}{( N + 1 ) * {Z}_{d} + R s + R L} , \qquad ( 11 )$$

the attenuation G2R_{c} of the second common-mode signals by the apparatus according to the present specific implementation is:

$$G 2 {R}_{c} \approx 20 * N * log ( \vert \frac{{Z}_{d}}{{Z}_{c}} \vert ) + 20 * log ( \vert \frac{R s}{{Z}_{c}} \vert ) . \qquad ( 12 )$$

The numerical comparison between the common-mode impedance Z_{c} of the wideband common-mode inductor and the differential mode impedance Z_{d} of the wideband common-mode inductor shown in FIG. 3C2 shows that the absolute value of Z_{c} is much larger than that of Z_{d}. Compared with the apparatus according to the first embodiment, the attenuations of the first common-mode signals and the second common-mode signals by the apparatus according to the present specific implementation are both increased by

$$- 20 * ( N - 1 ) * log ( \vert \frac{{Z}_{d}}{{Z}_{c}} \vert ) .$$

### [Variants of the Filtering Apparatuses According to the First and Second Embodiments]

The filtering apparatus according to the first embodiment and the filtering apparatus according to the second embodiment described above are two kinds of typical filtering apparatuses of the present disclosure. In some embodiments, variants are made to the filtering apparatus according to the first embodiment and the filtering apparatus according to the second embodiment, which variants are the same for the filtering apparatus according to the first embodiment and the filtering apparatus according to the second embodiment. Various variants are discussed below by taking the filtering apparatus according to the second embodiment as an example.

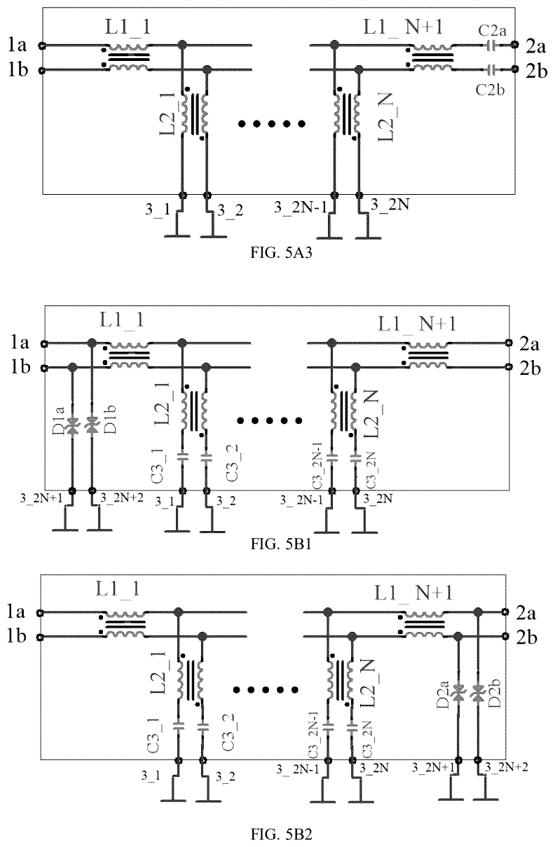

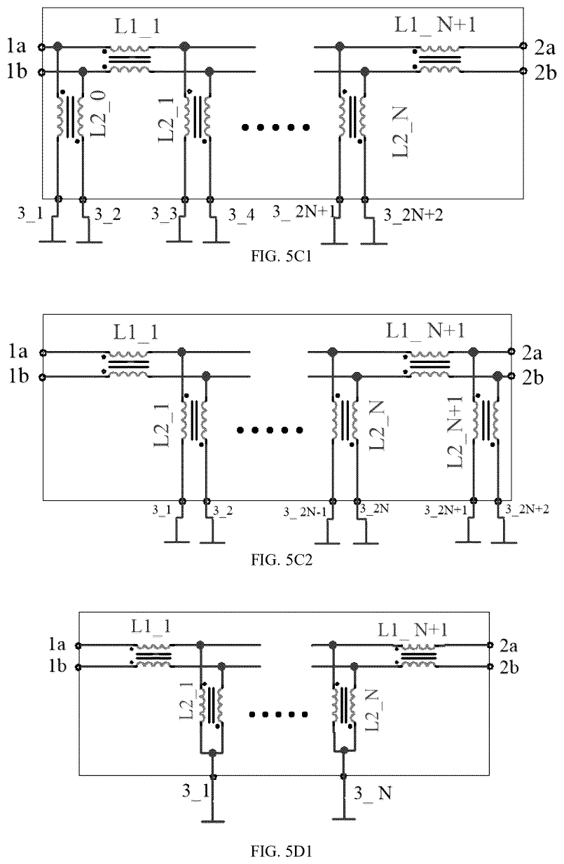

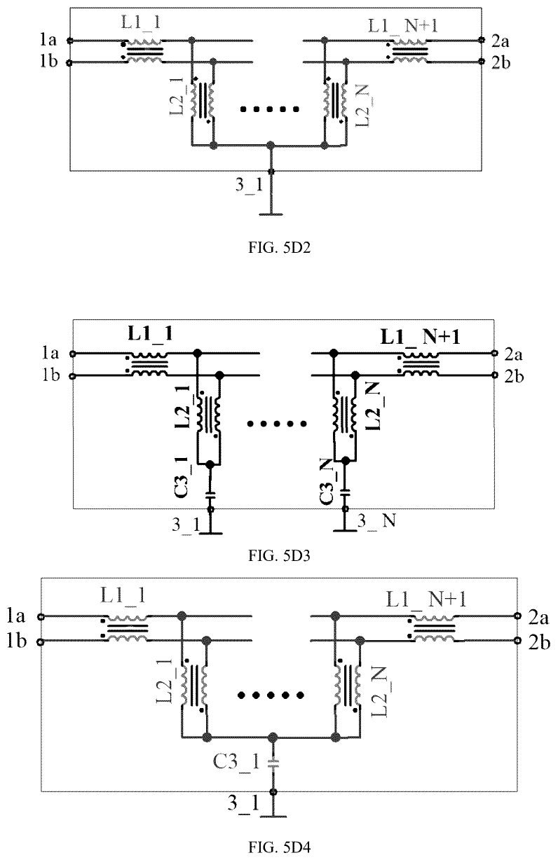

In a first variant of the filtering apparatus according to the second embodiment, the two coils of each of the differential-mode inductors L2_i (i=1, 2, . . . , N) of the filtering apparatus according to the second embodiment are each connected to the ground via a combination circuit, which may comprise a resistor, an inductor, a capacitor or a diode, and preferably comprises a capacitor. FIG. 5A1 is an exemplified circuit structure of the first variant of the filtering apparatus according to the second embodiment of the present disclosure, wherein the two coils of each of the differential-mode inductors L2_i (i=1, 2, . . . , N) are connected to the ground terminals 3_2i-1 and 3_2i of the apparatus via capacitors C3_2i-1 and C3_2i (i=1, 2, . . . ,N), respectively, and the ground terminals are connected to the ground respectively.

In a second variant of the filtering apparatus according to the second embodiment, the two input terminals of the filtering apparatus are each connected in series to a combination circuit for isolating the direct current signals at the input terminals of the differential line. The combination circuit may comprise a resistor, an inductor, a capacitor or a diode, and preferably comprises a capacitor. FIG. 5A2 is an exemplified circuit structure of the second variant of the filtering apparatus according to the second embodiment of the present disclosure, wherein the two input terminals 1a and 1b of the filtering apparatus are connected in series to capacitors C1a and C1b, respectively.

In a third variant of the filtering apparatus according to the second embodiment, the two output terminals of the filtering apparatus are each connected in series to a combination circuit for isolating the direct current signals at the output terminals of the differential line. The combination circuit may comprise a resistor, an inductor, a capacitor or a diode, and preferably comprises a capacitor. FIG. 5A3 is an exemplified circuit structure of the third variant of the filtering apparatus according to the second embodiment of the present disclosure, wherein the two out terminals 2a and 2b of the filtering apparatus are connected in series to capacitors C2a and C2b, respectively.

In a fourth variant of the filtering apparatus according to the second embodiment, a diode or a bi-directional diode is connected between each of the two input terminals of the filtering apparatus and the ground, for limiting an amplitude of the signals at the input terminals of the differential line, and also for anti-static protection. FIG. 5B1 is an exemplified circuit structure of the fourth variant of the filtering apparatus according to the second embodiment of the present disclosure, wherein a bi-directional diode D1b and a bi-directional diode D1a are connected between one of the two input terminals 1a and 1b of the apparatus and the ground, respectively.

In a fifth variant of the filtering apparatus according to the second embodiment, a diode or a bi-directional diode is connected between each of the two output terminals of the filtering apparatus and the ground, for limiting an amplitude of the signals at the output terminals of the differential line, and also for anti-static protection. FIG. 5B2 is an exemplified circuit structure of the fifth variant of the filtering apparatus according to the second embodiment of the present disclosure, wherein a bi-directional diode D2b and a bi-directional diode D2a are connected between one of the two output terminals 2a and 2b of the apparatus and the ground, respectively.

In a sixth variant of the filtering apparatus according to the second embodiment, each of the two coils of a differential-mode inductor is connected between one of the two input terminals of the filtering apparatus and the ground for performing impedance matching on the first common-mode signals at the input terminals of the differential line. FIG. 5C1 is an exemplified circuit structure of the sixth variant of the filtering apparatus according to the second embodiment of the present disclosure, wherein each of the two coils of a differential-mode inductor L2_0 is connected between one of the two input terminals 1a and 1b of the apparatus and the ground, respectively.

In a seventh variant of the filtering apparatus according to the second embodiment, each of the two coils of a differential-mode inductor is connected between one of the two output terminals of the filtering apparatus and the ground for performing impedance matching on the second common-mode signals at the output terminals of the differential line. FIG. 5C2 is an exemplified circuit structure of the seventh variant of the filtering apparatus according to the second embodiment of the present disclosure, wherein each of the two coils of a differential-mode inductor L2_N+1 is connected between one of the two output terminals 2a and 2b of the filtering apparatus and the ground, respectively.

In an eighth variant of the filtering apparatus according to the second embodiment, the ground terminals of each of the differential-mode inductors of the filtering apparatus according to the second embodiment are merged firstly and then connected to the ground to simplify the circuit. FIG. 5D1 is an exemplified circuit structure diagram of the eighth variant of the filtering apparatus according to the second embodiment of the present disclosure, wherein the ground terminals of the two coil of each differential-mode inductor L2_i (i=1, 2, . . . , N) are merged into a node, which is numbered as 3_i, and the node is then connected to the ground.

In a ninth variant of the filtering apparatus according to the second embodiment, the ground terminals of the differential-mode inductors of the filtering apparatus according to the second embodiment are merged firstly and connected then to the ground to simplify the circuit, and FIG. 5D2 is an exemplified circuit structure diagram of the ninth variant of the filtering apparatus according to the second embodiment of the present disclosure, wherein the ground terminals of the differential-mode inductors L2_i (i=1, 2, . . . , N) are merged into a node numbered as 3_1, and the node is then connected to the ground.

In a tenth variant of the filtering apparatus according to the second embodiment, the ground terminals of each of the differential-mode inductors of the filtering apparatus according to the second embodiment are merged and then connected to the ground via capacitors to simplify the circuit. FIG. 5D3 is an exemplified circuit structure diagram of the tenth variant of the filtering apparatus according to the second embodiment of the present disclosure, wherein the ground terminals of the two coils of each differential-mode inductor L2_i (i=1, 2, . . . , N) are merged into a node, which is connected to a node numbered as 3_i via a capacitor C3_i and then connected to the ground.

In an eleventh variant of the filtering apparatus according to the second embodiment, the ground terminals of the differential-mode inductors of the filtering apparatus according to the second embodiment are merged and then connected to the ground via a capacitor to simplify the circuit. FIG. 5D4 is an exemplified circuit structure diagram of the eleventh variant of the filtering apparatus according to the second embodiment of the present disclosure, wherein the ground terminals of the differential-mode inductors L2_i (i=1, 2, . . . , N) are merged into a node, which is then connected to a node numbered as 3_1 via a capacitor C3-1 and then connected to the ground.

In some embodiments, the first variant to the seventh variant of the filtering apparatus according to the second embodiment are combined accordingly to include any combination of the variants therein. FIG. 5E is a circuit structure of a combination of the first variant to the seventh variant of the filtering apparatus according to the second embodiment of the present disclosure.

In some embodiments, the eighth variant or the tenth variant of the filtering apparatus according to the second embodiment of the present disclosure is combined with at least one of the second variant to the seventh variant, or the ninth variant or the eleventh variant of the filtering apparatus according to the second embodiment of the present disclosure is combined with at least one of the second variant to the seventh variant.

### [Filtering Apparatus According to a Third Embodiment]

A filtering apparatus according to a third embodiment includes two common-mode inductors connected in series and two capacitors each connected between one of two branches of a differential line between the two inductors and the ground, to form a two-stage cascaded filtering of the common-mode signals, which can make full use of the frequency characteristics of the combination of a plurality of inductors and capacitors and have better filtering effect.

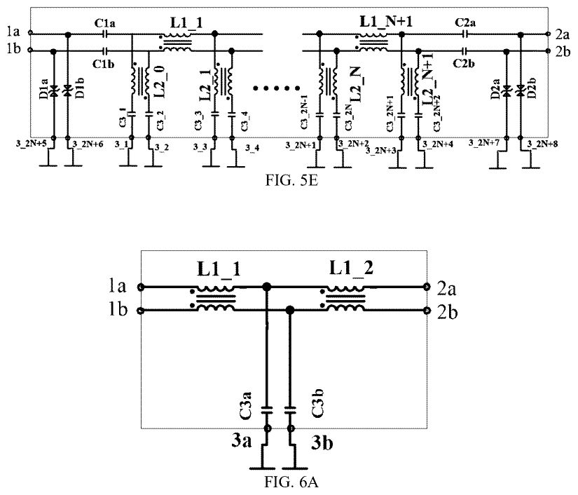

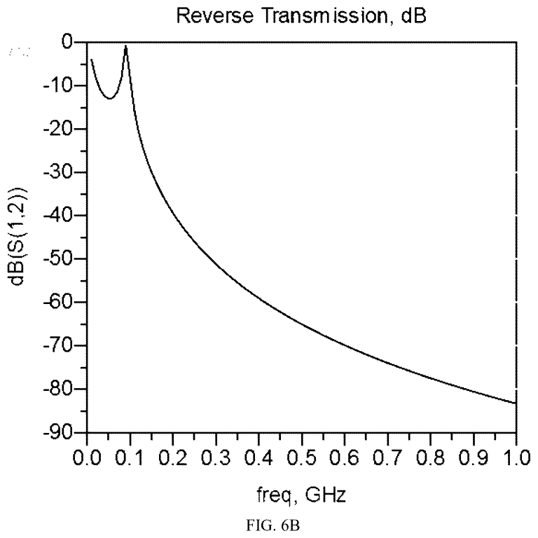

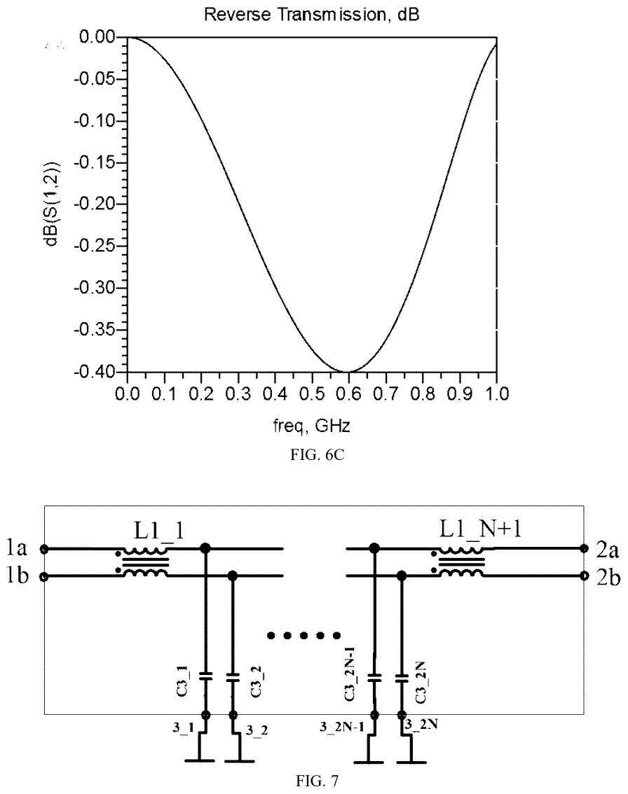

FIG. 6A shows a circuit structure of the filtering apparatus according to the third embodiment, which comprises a common-mode inductor L1_1, a capacitor C3a, a capacitor C3b, and a common-mode inductor L1_2 connected in a sequence, and magnetic fluxes generated by the two coils of each common-mode inductor when the common-mode signals flow through enhance each other. Wherein, the two coils of the common-mode inductor L1_1 are connected in series to the input terminals 1a and 1b of the filtering apparatus, respectively; the two coils of the common-mode inductor L1_2 are connected in series between the two coils of the common-mode inductor L1_1 and the output terminals 2a and 2b of the filtering apparatus, respectively; and the capacitor C3a and the capacitor C3b are connected between the two branches of the differential line between the two common-mode inductors and the ground terminals 3a and 3b, respectively.

Exemplarily, the two coils of each of the common-mode inductors in FIG. 6A are wound in the same direction, and if the two coils are wound in a clockwise direction or a counterclockwise direction, the current directions of the common-mode signals in the two coils are also in a clockwise direction or a counterclockwise direction. When the two coils of each of the common-mode inductors are wound in different directions, the current directions of the common mode signals thereof are also different. If one of the two coils is wound in the clockwise direction and the other is wound in the counterclockwise direction, one of the current directions of the common-mode signals in the two coils will be the clockwise direction, and the other will be the counterclockwise direction.

The components of the filtering apparatus according to the third embodiment are passive devices, the input terminals and the output terminals of the filtering apparatus are interchangeable and work on the same principle. The following descriptions assume that the input terminals are on the left side of the figures and the output terminals are on the right side of the figures.

The filtering effect of the filtering apparatus according to the third embodiment on the first common-mode signals propagating from left to right is first analyzed below, wherein the common-mode inductor L1_1, the capacitor C3a and the capacitor C3b form a first-stage filtering module C, and the common-mode inductor L1_2 and the load of the apparatus according to the third embodiment form a second-stage filtering module D. In the apparatus, capacitance values and inductance values are selected taking into account the frequency characteristics of the combination of a plurality of inductors and capacitors.

Exemplarily, it is assumed that L1_1 and L1_2 have the same parameters and their common-mode inductance values are 1 μH, C3a and C3b have the same parameters and their capacitance values are 3 pF, and the load resistance of the filtering apparatus according to the third embodiment is 50Ω and the output resistance of the upper-stage driving circuit is also 50Ω. FIG. 6B shows the attenuation of the first common-mode signals by the filtering apparatus according to the third embodiment, which is calculated based on the numerical values of the above examples. It may be seen from FIG. 6B that the attenuation value of the first common-mode signals by the filtering apparatus according to the third embodiment is already 65 dB at 500 Mhz, and exceeds 80 dB at 1 Ghz.

Because the filtering apparatus according to the third embodiment is symmetrical, the filtering effect on the second common-mode signals propagating from right to left is the same as the filtering effect on the first common-mode signals.

The filtering effect of the filtering apparatus according to the third embodiment on the differential-mode signals propagating from left to right is then analyzed below. Exemplarily, it is assumed that the differential-mode inductance values of L1_1 and L1_2 are 0.02 uH, the capacitance values of C3a and C3b are 3 pF, the load resistance of the filtering apparatus according to the third embodiment is 50Ω, and the output resistance of the upper stage driving circuit are also 50Ω. FIG. 6C shows the attenuation of the differential-mode signals by the filtering apparatus according to the third embodiment, which is calculated based on the numerical values described above. It may be seen from FIG. 6C that the impact of the filtering apparatus according to the third embodiment on the differential-mode signal is very small.

The various parameter settings in the filtering apparatus according to the third embodiment are an example, and may be designed according to specific scenarios in the actual use.

In summary, the filtering apparatus according to the third embodiment utilizes a filtering apparatus formed by two common-mode inductors connected in series and two capacitors connected between the differential line between the two inductors and the ground, to perform a two-stage cascaded filtering of the common-mode signals, which makes full use of the frequency characteristics of a combination of a plurality of inductors and capacitors to perform a two-stage attenuation on the common-mode signals sent from the differential signal transmission circuit, and better improves the signal-to-noise ratio of the differential line signals in a wider bandwidth. Meanwhile, it acts on and also performs the two-stage attenuation on the common-mode signals introduced from the loads of the differential signals and the common-mode signals introduced during the transmission, which has better attenuation effect and protects the differential signal transmission circuit. In addition, it also performs two-stage filtering of the plane noises and the common-mode signals coupled through the cable, which further improves the signal-to-noise ratio of the differential line signals, and further decreases outward radiation of the noises from the data cable by cascading to reduce the common-mode signals.

### [Filtering Apparatus According to a Fourth Embodiment]

The filtering apparatus according to the fourth embodiment has multiple same circuit combinations connected in a sequence after the filtering apparatus according to the third embodiment, each of which includes a common-mode inductor and two capacitors, to perform a multi-stage cascaded filtering of the common-mode signals.

FIG. 7 illustrates a structure of the filtering apparatus according to the fourth embodiment, which is formed by further connecting N−1 common-mode inductors and 2(N−1) capacitors behind the apparatus according to the third embodiment. The N−1 common-mode inductors are sequentially connected in series on the differential line and numbered as L1_3 to L1_N+1, wherein each of the two coils of each the common-mode inductors are connected in series on one branch of the differential line, and the 2(N−1) capacitors are connected on the differential line and numbered as C3-3 to C3_2N, respectively (For the purpose of uniform numbering, the capacitors C3a and C3b in FIG. 6A correspond to C3-1 and C3-2 in the present figure), wherein each of the capacitors is connected between one of the branches of the differential line between every two common-mode inductors and the ground.

Exemplarily, the two coils of each of the common-mode inductors in FIG. 7 are wound in the same direction, and if the two coils are each wound in the clockwise direction or the counterclockwise direction, the current directions of the common-mode signals in the two coils are each also the clockwise direction or the counterclockwise direction. When the two coils of each of the common-mode inductors are wound in different directions, the current directions of the common-mode signals thereof are also different. If one of the two coils is wound in the clockwise direction and the other is wound in the counterclockwise direction, one of the current directions of the common-mode signals in the two coils will be the clockwise direction, and the other will be the counterclockwise direction.

The components of the filtering apparatus according to the fourth embodiment are passive devices, and the input terminals and the output terminals of the filtering apparatus are interchangeable and work on the same principle. The following descriptions assume that the input terminals are on the left side of the figures and the output terminals are on the right side of the figures.

The filtering effect of the filtering apparatus according to the fourth embodiment on the first common-mode signals propagating from left to right is first analyzed below, wherein the common-mode inductors L1_i (i=1, 2, . . . ,N), the capacitors C3_2i-1 (i=1, 2, . . . ,N) and the capacitors C3_2i (i=1, 2, . . . ,N) form first-stage filtering modules C, the total number of which is N, and one common-mode inductor L1_N+1 and the load form a second-stage filtering module D, to achieve N+1-stages filtering of the first common-mode signals. Comparing with the filtering apparatus according to the third embodiment, N−1 first-stage filtering modules C is increased; and due to the increase of the inductors and the capacitors, there are more choices for adjusting the frequency characteristics of a combination of the inductors and the capacitors, and the filtering effect is further improved on the basis of the filtering apparatus according to the third embodiment.

Because the filtering apparatus according to the fourth embodiment is symmetrical, the filtering effect on the second common-mode signals propagating from right to left is the same as the filtering effect on the first common-mode signals, i.e., the filtering effect is further improved on the basis of the filtering apparatus according to the third embodiment.

The filtering effect of the filtering apparatus according to the fourth embodiment on the differential-mode signals propagating from left to right is then analyzed below, wherein although N−1 first-stage filtering modules C are increased, the attenuation of the differential-mode signals by the first-stage filtering modules C is small, and since the values of the parameters of the inductors and the capacitors may be adjusted and the overall frequency characteristics of the combination circuit may be optimized, the impact of the filtering apparatus according to the fourth embodiment on the differential-mode signals is small.

In summary, the filtering apparatus according to the fourth embodiment utilizes a filtering apparatus formed by at least three common-mode inductors connected in series and two capacitors connected between the differential line between every two adjacent common-mode inductors and the ground, to perform a multi-stage cascade attenuation of the common-mode signals sent from the differential signal transmission circuit, which further improves the attenuation effect on basis of the filtering apparatus according to the third embodiment, has small impact on the differential-mode signals and further improves the signal-to-noise ratio of the differential line signals in a wider bandwidth. Meanwhile, it also performs multi-stage attenuation on the common-mode signals introduced from the loads of the differential signals and the common-mode signals introduced during the transmission, which has good attenuation effect and protects the differential signal transmission circuit. In addition, it also performs multi-stage filtering on the plane noises and the common-mode signals coupled through the cable, which further improves the signal-to-noise ratio of the differential line signals, and further decreases outward radiation of the noises from the data cable by cascading to reduce the common-mode signals.

### [Variants of the Filtering Apparatuses According to the Third and Fourth Embodiments]

The filtering apparatus according to the third embodiment and the filtering apparatus according to the fourth embodiment are also two kinds of typical filtering apparatus of the present disclosure. In some embodiments, variants are made to the filtering apparatus according to the third embodiment and the filtering apparatus according to the fourth embodiment, which are the same for the filtering apparatus according to the third embodiment and the filtering apparatus according to the fourth embodiment. various variants are discussed below by taking the filtering apparatus according to the fourth embodiment as an example.

In a first variant of the filtering apparatus according to the fourth embodiment, a combination circuit consisting of a resistor and a capacitor connected in series is selected to replace the capacitors in the filtering apparatus according to the fourth embodiment.

In a second variant of the filtering apparatus according to the fourth embodiment, a capacitor or a combination circuit consisting of a resistor and a capacitor connected in series is connected between each of the two input terminals of the filtering apparatus and the ground to realize input impedance matching.

In a third variant of the filtering apparatus according to the fourth embodiment, a capacitor or a combination circuit consisting of a resistor and a capacitor connected in series is connected between each of the two output terminals of the filtering apparatus and the ground to realize output impedance matching.

In a fourth variant of the filtering apparatus according to the fourth embodiment, a diode or a bi-directional diode is connected between each of the two input terminals of the filtering apparatus and the ground to realize amplitude limiting and anti-static.

In a fifth variant of the filtering apparatus according to the fourth embodiment, a diode or a bi-directional diode is connected between each of the two output terminals of the filtering apparatus and the ground to realize amplitude limiting and anti-static.

In some embodiments, the first variant to the fifth variant of the filtering apparatus according to the fourth embodiment are combined accordingly, and FIG. 8 illustrates a circuit structure of a combination of the first variant to the fifth variant of the filtering apparatus according to the fourth embodiment of the present disclosure.

### [Filtering Apparatus According to a Fifth Embodiment]

In the filtering apparatus according to a fifth embodiment, the common-mode inductors in the filtering apparatus according to the first embodiment, the variants of the filtering apparatus according to the first embodiment, the filtering apparatus according to the second embodiment or the variants of the filtering apparatus according to the second embodiment are encapsulated in a device, with other circuit parts remaining unchanged.

### [Filtering Apparatus According to a Sixth Embodiment]

In the filtering apparatus according to a sixth embodiment, the common-mode inductors in the filtering apparatus according to the third embodiment, the variants of the filtering apparatus according to the third embodiment, the filtering apparatus according to the fourth embodiment or the variants of the filtering apparatus according to the fourth embodiment are encapsulated in a device, with other circuit parts remaining unchanged.

FIG. 11 illustrates a possible implementation of the filtering apparatus according to the sixth embodiment, in which the common-mode inductors of the filtering apparatus according to the third embodiment are encapsulated in a device, with other circuit parts remaining unchanged.

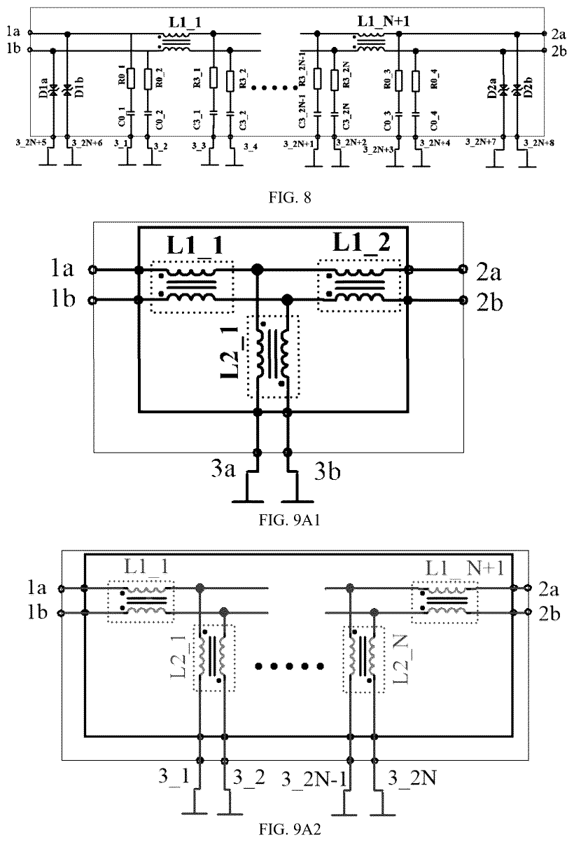

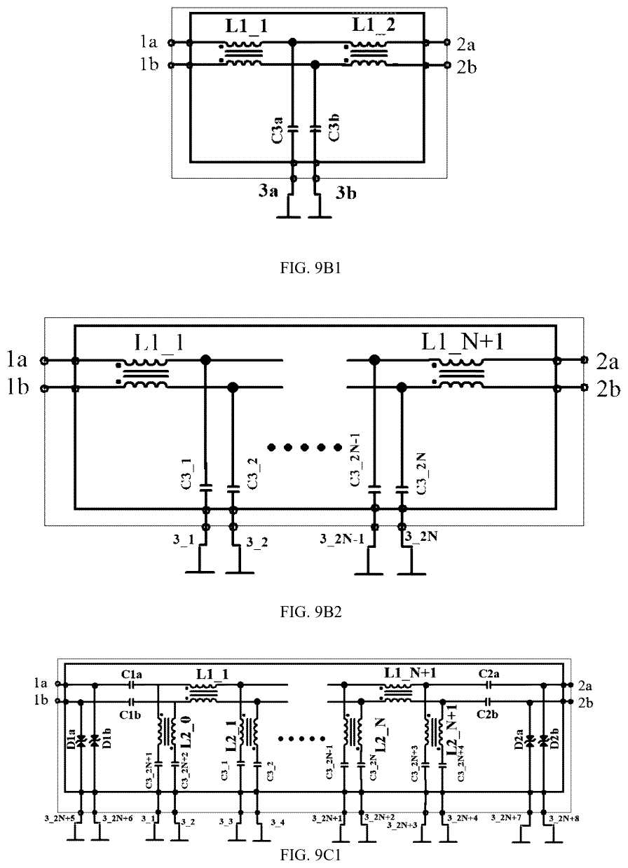

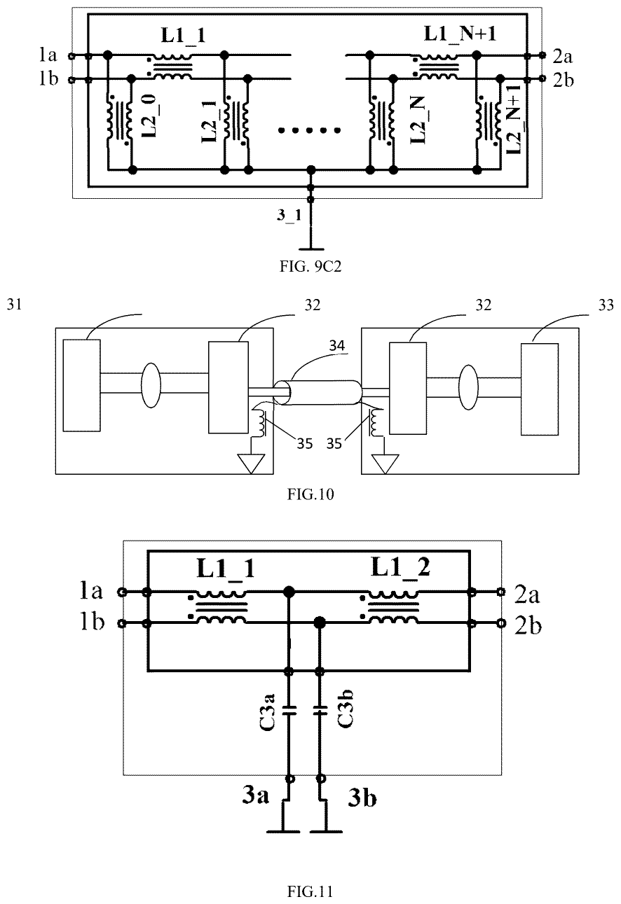

Devices according to embodiments of the present disclosure are described below in conjunction with FIGS. 9A1 to 9C2.

### [Devices According to the Embodiments]

Embodiments of the present disclosure also provide devices in which the filtering apparatuses according to the embodiments are encapsulated to achieve filtering of the common-mode signals, which includes the device according to a first embodiment, the device according to a second embodiment, the device according to a third embodiment, the device according to a fourth embodiment, and variants of the devices according to the embodiments and combinations thereof.

The device according to the first embodiment corresponds to the filtering apparatus according to the first embodiment, and FIG. 9A1 illustrates an internal circuit structure of the device according to the first embodiment, in which the common-mode inductors L1_1 and L1_2 and the differential-mode inductor L2_1 of the filtering apparatus according to the first embodiment as shown in FIG. 3A are encapsulated in a device. The device according to the first embodiment has input terminals 1a and 1b, output terminals 2a and 2b, and ground terminals 3a and 3b.

The advantages of the device according to the first embodiment are the same as those of the filtering apparatus according to the first embodiment and will not be repeated herein.

The device according to the second embodiment corresponds to the filtering apparatus according to the second embodiment, and FIG. 9A2 illustrates an internal circuit structure of the device according to the second embodiment, in which the common-mode inductors L1_i (i=1, 2, . . . , N+1) and the differential-mode inductors L2_i (i=1, 2, . . . , N) of the filtering apparatus according to the second embodiment as shown in FIG. 4A are encapsulated in a device, the device according to the second embodiment has input terminals 1a and 1b, output terminals 2a and 2b, and multiple ground terminals forming N groups and providing the ground for the coils of the differential-mode inductor L2_i (i=1, 2, . . . , N), respectively.

The advantages of the device according to the second embodiment are the same as those of the filtering apparatus according to the second embodiment and will not be repeated herein.

The device according to the third embodiment corresponds to the filtering apparatus according to the third embodiment, and FIG. 9B1 illustrates an internal circuit structure of the device according to the third embodiment, in which the common-mode inductors L1_1 and L1_2 and the capacitors C3a and C3b of the filtering apparatus according to the third embodiment as shown in FIG. are encapsulated in a device. The device according to the third embodiment has input terminals 1a and 1b, output terminals 2a and 2b, and ground terminals 3a and 3b.

The advantages of the device according to the third embodiment are the same as those of filtering apparatus according to the third embodiment and will not be repeated herein.

The device according to the fourth embodiment corresponds to the filtering apparatus according to the fourth embodiment, and FIG. 9B2 illustrates an internal circuit structure of the device according to the fourth embodiment, in which the common-mode inductors L1_i (i=1, 2, . . . , N+1) and the 2N capacitors of the filtering apparatus according to the fourth embodiment as shown in FIG. 7 are encapsulated in a device. The device according to the fourth embodiment has input terminals 1a and 1b, output terminals 2a and 2b, and a plurality of ground terminals forming N groups and providing the ground for the capacitors.

The advantages of the device according to the fourth embodiment are the same as those of the filtering apparatus according to the fourth embodiment and will not be repeated herein.

Different from the conventional differential filtering devices, parameters of the devices according to the embodiments are characterized by a high resistance to the common-mode signals between the two input terminals and the ground and between the two output terminals and the ground within its operating frequency range.

In some embodiments, variants of the devices according to the embodiments are also included.

Variants of the device according to the first embodiment and combinations thereof correspond to the variants of the filtering apparatus according to the first embodiment and the combinations thereof, respectively, in which the common-mode inductors, the differential-mode inductors, the unidirectional and bidirectional diodes, the capacitors and the resistors in the variants of the filtering apparatus according to the first embodiment or the combinations thereof are encapsulated in a device, and the manners to connect externally are the same as those of the filtering apparatus according to the first embodiment or the combinations thereof.

Variants of the device according to the second embodiment and combinations thereof correspond to the variants of the filtering apparatus according to the second embodiment and the combinations thereof, respectively, in which the common-mode inductors, the differential-mode inductors, the unidirectional and bidirectional diodes, the capacitors and the resistors in the variants of the filtering apparatus according to the second embodiment or the combinations thereof are encapsulated in a device, and the manners to connect externally are the same as those of the filtering apparatus according to the second embodiment or the combinations thereof.

Variants of the device according to the third embodiment and combinations thereof correspond to the variants of the filtering apparatus according to the third embodiment and the combinations thereof, respectively, in which the common-mode inductors, the differential-mode inductors, the unidirectional and bidirectional diodes, the capacitors and the resistors in the variants of the filtering apparatus according to the third embodiment or the combinations thereof are encapsulated in a device, and the manners to connect externally are the same as those of the filtering apparatus according to the third embodiment or the combinations thereof.

Variants of the device according to the fourth embodiment and combinations thereof correspond to the variants of the filtering apparatus according to the fourth embodiment and the combinations thereof, respectively, in which the common-mode inductors, the differential-mode inductors, the unidirectional and bidirectional diodes, the capacitors and the resistors in the variants of the filtering apparatus according to the fourth embodiment or the combinations thereof are encapsulated in a device, and the manners to connect externally are the same as those of the filtering apparatus according to the fourth embodiment or the combinations thereof.

The variants of the devices according to the embodiments or the combinations thereof are described below by taking the variants of the device according to the second embodiment as an example. A first variant to an eleventh variant of the device according to the second embodiment correspond to the first variant to the eleventh variant of the filtering apparatus according to the second embodiment, and the combinations of the device according to the second embodiment correspond to the combinations of the corresponding variants of the filtering apparatus according to the second embodiment.

FIG. 9C1 illustrates an exemplified structure diagram of a combination of the first variant to the seventh variant of the device according to the second embodiment, which corresponds to the combination of the first variant to the seventh variant of the filtering apparatus according to the second embodiment. On the basis of the device according to the second embodiment, the inside of the device further includes the following components: ground capacitors C2i-1 and C2i for the differential-mode inductors L2_i, input capacitors C1a and C1b, output capacitors C2a and C3b, a differential-mode inductor L2_0 and a differential-mode inductor L2_N+1 for impedance matching, diodes D1a and D1b for input amplitude limiting, and diodes D2a and D2b for output amplitude limiting.

FIG. 9C2 illustrates a structure diagram of the eleventh variant of the device according to the second embodiment, which corresponds to the eleventh variant of the filtering apparatus according to the second embodiment, wherein the ground terminals of the coils of the differential-mode inductors L2_i (i=1, 2, . . . , N) are merged into a node numbered as 3_1 and then connected to the ground. Thus, the number of ground terminals of the whole device according to the embodiment becomes one, simplifying the manner to connect externally.

The devices according to the embodiments use passive components, and when they are symmetrical circuits, the input terminals and the output terminals are interchangeable.

A transmission apparatus according to an embodiment of the present disclosure is described below in connection with FIG. 10.

### [Transmission Apparatus According to an Embodiment]

An embodiment of the present disclosure also provides a transmission apparatus for propagating the differential-mode signals, which comprises a differential cable, and a first apparatus to which both ends of the differential cable are connected. The first apparatus may be the device according to any embodiment of the present disclosure or a variant thereof or a combination of the variants thereof, or the first apparatus may also be the filtering apparatus according to any embodiment or a variant thereof or a combination of the variants thereof. Wherein the shielding layer of the differential cable may be not connected to the ground, or may be connected to the ground via an inductor, or may be connected to the ground via a magnetic bead.

FIG. 10 illustrates a structure of an application scenario of the transmission apparatus according to an embodiment, which adds two inductors 35 on basis of FIG. 2, wherein each of two ends of the differential cable 34 is connected to the ground via one inductor 35. The differential cable 34, two filtering circuits 32 and two inductors 35 in the dashed box of FIG. 10 form a transmission apparatus according to an embodiment.

The shielding layer of the differential cable 34 is connected to the ground in the disclosed technology, to mainly provide a return path for the common-mode signals in the differential cable 34. The common-mode signals in the differential cable 34 may induce currents in opposite directions in the shielding layer, thereby reducing outward radiation when superimposed with the common-mode signals.

When the filtering circuits 32 use the filtering apparatus according to any embodiment of the present disclosure or the variant thereof or a combination of the variants thereof, or when the filtering circuits 32 use the filtering device according to any embodiment of the present disclosure or a variation thereof or a combination of the variants thereof, the common-mode signals in the differential cable 34 are attenuated to a very small extent, and then the main source of radiation on the differential cable 34 is the common-mode noises coupled to the shielding layer of the differential cable 34 by the ground line. At this time, the shielding layer of the differential cable 34 is isolated from the ground by the inductors 35 to reduce the common-mode noises coupled to the shielding layer of the differential cable 34 by the ground line.

In FIG. 10, the shielding layer of the differential cable 34 may also be isolated from the ground by not being connected to the ground or through the magnetic bead or other filtering device for filtering out the corresponding frequency band.

Note that the foregoing is only preferred embodiments of the present disclosure and the technical principles utilized. Those skilled in the art will understand that the present disclosure is not limited to the particular embodiments described herein, and those skilled in the art can make various obvious variations, readjustments, and substitutions without departing from the scope of protection of the present disclosure. Therefore, although the above embodiments illustrate the present disclosure in some detail, the present disclosure is not limited to the above embodiments, but may include more equivalent embodiments without departing from the idea of the present disclosure, all of which fall within the scope of protection of the present disclosure.

1. A filtering apparatus for filtering common-mode signals in a differential line, comprising:
at least two common-mode inductors, wherein the common-mode inductors each are a choke having two coils, and magnetic fluxes generated by the two coils of each of the common-mode inductors when common-mode signals flow through enhance each other, and wherein one coil of each of the common-mode inductors is connected in series to one branch of the differential line in a sequence, and the other coil of each of the common-mode inductors is connected in series to the other branch of the differential line in the sequence; and
at least one differential-mode inductor, wherein the at least one differential-mode inductor each is a choke having two coils, and magnetic fluxes generated by the two coils of each of the at least one differential-mode inductor when the common-mode signals flow through counteract each other, wherein each coil of each of the at least one differential-mode inductor is connected between one of two branches of the differential line between adjacent common-mode inductors and the ground.

2. The filtering apparatus according to claim 1, further comprising at least one of:
a differential-mode inductor connected between input terminals of the filtering apparatus and the ground, two coils of which are connected between the two branches of the differential line at the input terminals of the filtering apparatus and the ground, respectively;
a differential-mode inductor connected between output terminals of the filtering apparatus and the ground, two coils of which are connected between the two branches of the differential line at the output terminals of the filtering apparatus and the ground, respectively;
diodes connected between the two branches of the differential line at the input terminals of the filtering apparatus and the ground;
diodes connected between the two branches of the differential line at the output terminals of the filtering apparatus and the ground;
third circuits connected in series to the two branches of the differential line at the input terminals of the filtering apparatus, respectively, wherein the third circuits each includes at least one of an inductor, a resistor, a capacitor and a diode; and
third circuits connected in series to the two branches of the differential line at the output terminals of the filtering apparatus.

3. The filtering apparatus according to claim 2, further comprising:
fourth circuits connected between ground ends of the two coils of each of the differential-mode inductors and the ground, wherein the fourth circuits each includes at least one of an inductor, a resistor, a capacitor, and a diode.

4. A filtering apparatus for filtering common-mode signals in a differential line, comprising:
at least two common-mode inductors, wherein the common-mode inductors each are a choke having two coils and magnetic fluxes generated by the two coils of each of the common-mode inductors when common-mode signals flow through enhance each other, and wherein one coil of each of the common-mode inductors is connected in series to one branch of the differential line in a sequence, and the other coil of each of the common-mode inductors is connected in series to the other branch of the differential line in the sequence; and
at least one first circuit, wherein the at least one first circuit each includes two second circuits, which each is a capacitor or a series circuit of a capacitor and a resistor, and wherein each of the second circuits is connected between one of two branches of the differential line between adjacent common-mode inductors and the ground.

5. The filtering apparatus according to claim 4, further comprising at least one of:
second circuits connected between the two branches of the differential line at input terminals of the filtering apparatus and the ground;
second circuits connected between the two branches of the differential line at output terminals of the filtering apparatus and the ground;
diodes connected between the two branches of the differential line at the input terminals of the filtering apparatus and the ground; and
diodes connected between the two branches of the differential line at the output terminals of the filtering apparatus and the ground.

6. (canceled)

7. (canceled)

8. (canceled)

9. A transmission apparatus, comprising:
a differential cable,
wherein both ends of the differential cable are connected to a filtering apparatus, said filtering apparatus including at least two common-mode inductors, wherein the common-mode inductors each are a choke having two coils, and magnetic fluxes generated by the two coils of each of the common-mode inductors when common-mode signals flow through enhance each other, and wherein one coil of each of the common-mode inductors is connected in series to one branch of the differential cable in a sequence, and the other coil of each of the common-mode inductors is connected in series to the other branch of the differential cable in the sequence.

10. The transmission apparatus according to claim 9, wherein used between a shielding line at the both ends of the differential cable and the ground is any of the following connection manners:
no connection;
connection via an inductor; and
connection via a magnetic bead.

11. The transmission apparatus according to claim 9, wherein the filtering apparatus further includes at least one differential-mode inductor, wherein the at least one differential-mode inductor each is a choke having two coils, and magnetic fluxes generated by the two coils of each of the at least one differential-mode inductor when the common-mode signals flow through counteract each other, wherein each coil of each of the at least one differential-mode inductor is connected between one of two branches of the differential cable between adjacent common-mode inductors and the ground.

12. The transmission apparatus according to claim 11, wherein the filtering apparatus further includes at least one of:
a differential-mode inductor connected between input terminals of the filtering apparatus and the ground, two coils of which are connected between the two branches of the differential cable at the input terminals of the filtering apparatus and the ground, respectively;
a differential-mode inductor connected between output terminals of the filtering apparatus and the ground, two coils of which are connected between the two branches of the differential cable at the output terminals of the filtering apparatus and the ground, respectively;
diodes connected between the two branches of the differential cable at the input terminals of the filtering apparatus and the ground;
diodes connected between the two branches of the differential cable at the output terminals of the filtering apparatus and the ground;
third circuits connected in series to the two branches of the differential cable at the input terminals of the filtering apparatus, respectively, wherein the third circuits each includes at least one of an inductor, a resistor, a capacitor and a diode; and
third circuits connected in series to the two branches of the differential cable at the output terminals of the filtering apparatus.

13. The transmission apparatus according to claim 12, wherein the filtering apparatus further includes fourth circuits connected between ground ends of the two coils of each of the differential-mode inductors and the ground, wherein the fourth circuits each includes at least one of an inductor, a resistor, a capacitor, and a diode.

14. The transmission apparatus according to claim 9, wherein the filtering apparatus further includes at least one first circuit, wherein the at least one first circuit each includes two second circuits, which each is a capacitor or a series circuit of a capacitor and a resistor, and wherein each of the second circuits is connected between one of two branches of the differential cable between adjacent common-mode inductors and the ground.

15. The transmission apparatus according to claim 14, wherein the filtering apparatus further includes at least one of:
second circuits connected between the two branches of the differential cable at input terminals of the filtering apparatus and the ground;
second circuits connected between the two branches of the differential cable at output terminals of the filtering apparatus and the ground;
diodes connected between the two branches of the differential cable at the input terminals of the filtering apparatus and the ground; and
diodes connected between the two branches of the differential cable at the output terminals of the filtering apparatus and the ground.
